(19) United States
(12) Patent Application Publication
(10) Pub. No.: US 2012/0049095 A1
(43) Pub. Date: Mar. 1, 2012

(54) POLYMER ACTUATOR AND VALVE USING THE SAME

(76) Inventor: Tomoya Yamasaki, Yamanashi (JP)

(21) Appl. No.: 13/319,176

(22) PCT Filed: Mar. 10, 2011
(86) PCT No.: PCT/JP2011/055607

§ 371 Date: Nov. 7, 2011

(30) Foreign Application Priority Data
Mar. 11, 2010 (JP) 2010-054759
Jun. 16, 2010 (JP) 2010-137285

(51) Int. Cl. F16K 31/02; H01L 41/09

(52) U.S. Cl. 251/129.01; 310/330

(57) ABSTRACT

The object is to provide a polymer actuator capable of securing high sealability in spite of a simple interior structure, controlling opening and closing of the fluid passage or flow rate while increasing the amount of displacement at a small amount of applied voltage, and controlling the flow rate from small flow rate to large flow rate through variation in the applied voltage, thereby enhancing response performance and to provide a valve using the polymer actuator. The polymer actuator includes a power driver 2 deformed upon receiving external electro stimuli and fixed electrodes 3 and 4 disposed on upper and lower surface sides of the power driver 2 in an opposite manner for applying positive and negative external electro stimuli to the power driver 2 in a planar fashion, wherein at least one of the fixed electrodes 3 and 4 extends to a side, on which the power driver is bent and deformed, and has an abutment surface 5 displaced by means of the Coulomb force when the power driver 2 has been deformed, thereby enabling the abutment surface to come into contact with the power driver and, at the time of application of no external electro stimuli, the abutment surface 5 of one of the fixed electrodes forms a spaced-apart region T between itself and the power driver 2.

### TECHNICAL FIELD

The present invention relates to a polymer actuator using a polymer material and to a valve suitable for opening and closing of a flow passage or control of a flow rate using the polymer actuator.

### BACKGROUND ART

In the case of sealing a fluid at all times for controlling a flow passage within a container, for example, a shaft-sealing device using a sealing member, such as an O-ring, has heretofore been utilized in general. Since the shaft-sealing device has to, as the first object, heighten its sealing function using the sealing member, the location of the sealing member or a fluid-sealing region is generally determined at a prescribed position. For this reason, assuming that the shaft-sealing device is operated to change over from the sealing region to a fluid-unsealing region for intending to open/close the fluid or control the flow rate, a section to which the sealing member in the sealing region or a housing is to be attached has to be equipped with a separate motion mechanism, such as a screw-feeding mechanism.

On one hand, a vale using a polymer actuator has been known to the art as a valve for switching a sealing region to an open or closed state (refer to Patent Document 1, for example). This valve uses a so-called artificial muscle as a valving element, and deformation of the valving element can switch a flow passage. The artificial muscle has an EPAM (Electroactive Polymer Artificial Muscle) structure in which the thin rubber-like polymer film (elastomer) is sandwiched between elastic electrodes and, when voltage has been applied between the electrodes, the polymer film is elongated in a planar direction.

On the other hand, the present applicant has proposed a shaft-sealing device of Patent Document 2. The shaft-sealing device of Document 2 is a shaft-sealing device using a polymer material, in which a shaft-sealing portion has a shaft-sealing body disposed thereon and made of a polymer material capable of being expanded and contracted, or deformed, through application of electrical stimuli to the shaft-sealing portion, and the shaft-sealing portion is provided with a flow passage to which a fluid leaking through the expansion or deformation of the shaft-sealing body flows. In the shaft-sealing device, the shaft-sealing body is formed in the shape of a substantially circular disc having parallel upper and lower surfaces and has the center portions of the upper and lower surfaces clamped between a pair of fixed electrodes. The paired fixed electrodes have substantially the same shape in the axial direction and are disposed in a state in which electrode portions abut on the shaft-sealing body. With this, portions of a power driver extending from the electrodes in the radial direction constitute bent sections.

### PRIOR ART DOCUMENT

Patent Document 1: Japanese Patent No. 3501216
Patent Document 2: Japanese Patent No. 4394749

### SUMMARY OF THE INVENTION

### Problems the Invention Intends to Solve

In the shaft-sealing device using the sealing member, however, since contact or slide of the motion mechanism is induced when switching between the sealing region and the unsealing region, wear is easy to occur at the sealing member or a slide portion, and it is difficult to sufficiently secure the sealability. For this reason, this shaft-sealing device is not suitable for opening and closing the flow passage or controlling the flow rate.

In the valve of Patent Document 1, since fluid pressure is received on the overall EPAM at the time of sealing the fluid, the EPAM is required to have a large pressure capacity and a large sealing force. In addition, the main body has to be provided therein with a separate sealing mechanism and a valve seat, thereby making the interior structure complicated. Furthermore, since the valve has the electrodes disposed on the entire voltage application region of the polymer film, when the polymer film is used as a movable portion of the valving element of the valve or the actuator for the valving element, the amount of deformation relative to applied energy becomes small to make the valve become less efficiency. Thus, the valve is used for a valve having a relatively small valve bore and has little practical value for controlling the flow amount at a large flow rate.

The shaft-sealing device of Patent Document 2 can control the amount of a leaking fluid at high accuracy while preventing wear during movement of the shaft-sealing body to maintain high sealing performance, allowing fluid flow at a prescribed flow rate in spite of the simple interior structure, and adjusting the amount of expansion and contraction, or deformation, of the shaft-sealing body through adjustment of an external electrical signal and, therefore, can substitute for an electromagnetic valve and be utilized for other various applications. However, since the shaft-sealing device necessitates large applied voltage of several kV or more in order to sufficiently displace the shaft-sealing body in the air, it is desired to reduce the applied voltage while securing the amount of displacement in order to make it practicable for opening and closing of the flow passage or control of the flow rate. In this case, it is preferred that the applied voltage of 1 kV or less be realized while maintaining the amount of displacement of the shaft-sealing body.

The present invention has been developed as a result of keen studies on the aforementioned state of affairs and the object thereof is to provide a polymer actuator capable of securing high sealability in spite of a simple interior structure, controlling opening and closing of the fluid passage or flow rate while increasing the amount of displacement at a small amount of applied voltage, and controlling the flow rate from small flow rate to large flow rate through variation in the applied voltage, thereby enhancing response performance and to provide a valve using the polymer actuator.

### Means for Solving the Problems

To attain the above object, the invention set forth in claim 1 is directed to a polymer actuator comprising a power driver deformed upon receiving external electro stimuli and fixed electrodes disposed on upper and lower surface sides of the power driver in an opposite manner for applying positive and negative external electro stimuli to the power driver in a planar fashion, wherein at least one of the fixed electrodes extends to a side, on which the power driver is deformed, and has an abutment surface displaced by means of the Coulomb force when the power driver has been deformed, thereby enabling the abutment surface to come into contact with the power driver and, at a time of application of no external electro stimuli, the abutment surface of one of the fixed electrodes forms a spaced-apart region between itself and the power driver.

The invention set forth in claim 2 is directed to the above polymer actuator, wherein the spaced-apart region is provided with an inclined surface, including a circular arc surface, a radiation surface and a tapered surface, with which the abutment surface and the power driver are gradually spaced apart from each other in an outer end direction.

The invention set forth in claim 3 is directed to the above polymer actuator, wherein the spaced-apart region is provided with a stepped region.

The invention set forth in claim 4 is directed to the above polymer actuator, wherein the power driver has a flexible electrode disposed on a surface opposite to at least the abutment surface and deformed together with the power driver to apply external electro stimuli to the power driver.

The invention set forth in claim 5 is directed to the above polymer actuator, further comprising a driving member comprising power drivers stacked via the flexible electrode in claim 4 to form a stacked power driver, wherein the stacked power driver has a fixed electrode disposed thereon to enhance response performance of the driving member.

The invention set forth in claim 6 is directed to the above polymer actuator, wherein the abutment surface has surface roughness of 25 to 500.

The invention set forth in claim 7 is directed to a valve using the above polymer actuator, comprising a body provided therein with plural flow passages and having the polymer actuator disposed therein as a valving element for controlling opening and closing the flow passages or controlling flow rate.

The invention set forth in claim 8 is directed to the above polymer actuator, wherein the power driver is used as a pilot valve for opening and closing a diaphragm- or piston-type main valve.

The invention set forth in claim 9 is directed to the above polymer actuator, wherein the pilot valve has a valve seat portion that is provided on a circumference thereof with plural bored orifices allowed to communicate with a communication passage on a secondary side.

The invention set forth in claim 10 is directed to the above polymer actuator, wherein the plural orifices have a total flow passage area larger than a flow passage area of through-bores formed in the main valve, and plural orifices having small diameters are disposed to cause generated stress in the polymer actuator to act on fluid pressure load, thereby driving the pilot valve.

The invention set forth in claim 11 is directed to a valve using the above polymer actuator having the valve seat portion that is provided with the plural orifices, wherein the orifices have a diameter respectively in the range of 0.25 to 0.5 mm.

The invention set forth in claim 12 is directed to the above valve using the above polymer actuator having the valve seat portion that is provided with the plural orifices, wherein the orifices respectively have a diameter of 0.25 mm or less.

The invention set forth in claim 13 is directed to the above valve using the above polymer actuator that has the valve seat portion provided on the circumference thereof with the plural orifices, wherein the orifices are disposed at a prescribed pitch.

The invention set forth in claim 14 is directed to the above valve using the above polymer actuator, wherein the prescribed pitch is in the range of 1.8 to 5.5 mm.

### Effects of the Invention

According to the invention set forth in claim 1, by using EPAM configured so as to deform the power driver with external electro stimuli from the fixed electrodes, it is possible to control opening and closing of the flow passage or flow rate while preventing occurrence of slide or contact and securing high sealability without the necessity of providing a separate motion mechanism. Since at least one of the upper and lower fixed electrodes extends to the side, on which the power driver is bent and deformed, and has the abutment surface displaced by means of the Coulomb force when the power driver has been deformed, thereby enabling the abutment surface to come into contact with the power driver and, at the time of applying no external electro stimuli, since the abutment surface forms the spaced-apart region between itself and the power driver, the great Coulomb force is exerted on the spaced-apart region every time the power driver is deformed to shorten the distance between itself and the electrodes at the time of application of voltage and, by means of the Coulomb force, attraction between the power driver and the electrodes is induced to promote the deformation of the power driver. For this reason, it is possible to increase the amount of displacement of the power driver with a small amount of applied voltage. Furthermore, it is also possible to adjust the amount of displacement of the power driver through adjustment of the applied voltage and to control the opening and closing operation with high accuracy or control the flow rate from small flow rate to large flow rate through variation of the applied voltage. Moreover, since the power driver to which the highest voltage has been applied is deformed so as to go along the abutment surface, the power driver is deformed in a substantially constant form at the time of application of the highest voltage to enable the state of the flow passage to be maintained stably.

According to the invention set forth in claim 2, by providing the spaced-apart region with the inclined surface, the Coulomb force arising from deformation of the power driver when voltage has been applied to the fixed electrodes can proportionately be increased and, with the increased Coulomb force, the power driver is smoothly displaced while the amount of displacement is increased with the small amount of applied voltage to thereby make it possible to control the opening and closing operation or the flow rate with high accuracy.

According to the invention set forth in claim 3, by providing the spaced-apart region with the stepped region, it is possible to space the abutment surface apart from the power driver without performing high-accuracy processing and to increase the Coulomb force between the abutment surface and the power driver via the stepped region, thereby making it possible to increase the amount of displacement of the power driver with the small amount of applied voltage.

According to the invention set forth in claim 4, by providing the power driver with the flexible electrode, a voltage application region is increase to enable the power driver to be displaced further greatly.

According to the invention set forth in claim 5, by preparing the stacked power driver and providing the stacked power driver with a fixed electrode, the response performance relative to the deformation is enhanced to enable the response speed to be accelerated at the time of closing the flow passage, for example.

According to the invention set forth in claim 6, by causing the abutment surface to have surface roughness of 25 or more, the responsiveness of the power driver to the voltage is heightened to enable the relation between the applied voltage and the amount of displacement of the power driver to become close to proportionate relationship. As a result, it is possible to adjust the amount of displacement relative to the applied voltage with high accuracy and also possible to control minute flow rate.

According to the invention set forth in claim 7, the entire structure can be simplified to attain compactness and, furthermore, the polymer actuator enables highly accurate opening and closing control and flow rate control.

According to the invention set forth in claim 8, it is possible to provide a valve having the entire structure simplified to attain compactness as compared with a conventional electromagnetic valve, control opening and closing the main valve through the highly accurate operation of the power driver with small power consumption while reducing the number of component parts and enhancing easiness of assemblage, and provide the pilot valve excellent in functionality as a substitute for the conventional electromagnetic valve.

According to the invention set forth in claim 9, by boring the plural orifices in the valve seat portion, it is possible to increase the flow rate of the pilot valve and, by allowing the orifices to communicate with the communication passage, it is possible to further increase the flow rate of the fluid flowing to the secondary side.

According to the invention set forth in claim 10, by disposing the small-diameter orifices at plural places to cause the generated stress in the polymer actuator to efficiently act on the pressure load, thereby enabling high-pressure large flow rate in the drive of the pilot valve to be secured, it is possible to provide the flow-rate controllable main valve with the pilot valve to attain pressure and flow-rate control at a similar or more level as compared with a pilot valve using a solenoid.

According to the invention set forth in claim 11, by providing the plural orifices having the diameter in the range of 0.25 to 0.5 mm, it is possible to provide the pilot valve capable of obtaining a prescribed flow rate relative to prescribed pressure. Furthermore, when the total area of the orifices is made constant, by making the orifice diameter small, it is possible to provide the high-pressure and large-flow-rate pilot valve.

According to the invention set forth in claim 12, by causing the orifices to have the diameter of 0.25 mm or less, it is possible to provide the highly accurate pilot valve capable of obtaining the prescribed flow rate through the substantially proportionate relationship between the pressure and the amount of displacement of the power driver. In this case, by changing the number of orifices while maintaining the constant total area in accordance with the pressure fluctuation range, it is possible to provide the pilot valve capable of obtaining the prescribed flow rate relative to the pressure.

According to the invention set forth in claim 13, by disposing the plural orifices on the circumference of the valve seat portion at the prescribed pitch, since it is possible to uniformly deform the entire polymer actuator relative to the orifices at the time of voltage application, it is possible to effectively generate the stress to enable the pilot valve to be operated. Furthermore according to the invention set forth in claim 14, since the prescribed pitch can be set to a proper value, it is possible to operate the polymer actuator with higher accuracy.

### BRIEF DESCRIPTION OF THE DRAWINGS

FIG. 1 is a schematic cross section of a polymer actuator according to the first embodiment of the present invention.

FIG. 2 includes schematic views showing the states of deformation of the polymer actuator in FIG. 1.

FIG. 3 is a schematic view showing a comparative example for comparison with the polymer actuator of the present invention.

FIG. 4 is a schematic cross section of a polymer actuator according the second embodiment of the present invention.

FIG. 5 is a schematic cross section of a polymer actuator according the third embodiment of the present invention.

FIG. 6 is a schematic cross section of a polymer actuator according the fourth embodiment of the present invention.

FIG. 7 is a schematic cross section of a polymer actuator according the fifth embodiment of the present invention.

FIG. 8 is a schematic cross section of a polymer actuator according the sixth embodiment of the present invention.

FIG. 9 is a schematic cross section of a polymer actuator according the seventh embodiment of the present invention.

FIG. 10 is a schematic cross section of a polymer actuator according the eighth embodiment of the present invention.

FIG. 11 is a schematic cross section showing an embodiment of a valve using the polymer actuator according to the present invention.

FIG. 12 is a schematic cross section showing a valve-opening state of the valve in FIG. 11.

FIG. 13 is a schematic cross section showing another embodiment of the valve using the polymer actuator according to the present invention.

FIG. 14 is a schematic view showing a displacement measurement device.

FIG. 15 is a schematic view showing the state of bend and deformation of a body to be measured.

FIG. 16 is a schematic cross section showing the principal part of a sample A.

FIG. 17 is a schematic cross section showing the principal part of a comparative sample a.

FIG. 18 includes graphs showing applied voltage and the amount of displacement of a power driver relative to the sample A.

FIG. 19 is includes graphs showing applied voltage and the amount of displacement of a power driver relative to the comparative sample a.

FIG. 20 is a schematic cross section showing the principal part of a sample B.

FIG. 21 is a schematic cross section showing the principal part of a comparative sample b.

FIG. 22 includes graphs showing applied voltage and the amount of displacement of a power driver relative to the sample B.

FIG. 23 includes graphs showing applied voltage and the amount of displacement of a power driver relative to the comparative sample b.

FIG. 24 is a schematic cross section showing the principal part of a sample C.

FIG. 25 includes graphs showing applied voltage and the amount of displacement of a power driver relative to the sample C.

FIG. 26 is a schematic cross section showing the principal part of a sample D.

FIG. 27 includes graphs showing applied voltage and the amount of displacement of a power driver relative to the sample D.

FIG. 28 is a schematic cross section showing the principal part of a sample E.

FIG. 29 is a graph showing applied voltage and the amount of displacement of a power driver relative to the sample E.

FIG. 30 is a graph showing applied voltage and the amount of displacement of a power driver relative to the sample F.

FIG. 31 is a graph showing the variation in amount of displacement relative to the voltage in FIG. 29.

FIG. 32 is a graph showing the variation in amount of displacement relative to the voltage in FIG. 30.

FIG. 33 is a schematic cross section showing still another embodiment of the valve using the polymer actuator according to the present invention.

FIG. 34 is a partially enlarged view of FIG. 33.

FIG. 35 is a schematic view showing orifices in FIG. 33.

FIG. 36 is a graph showing the relationship between the pressures and the flow rates of pilot valves having different orifice diameters.

FIG. 37 is a graph showing the relationship between the pressures and the flow rates of pilot valves having different numbers of orifices.

FIG. 38 is a graph showing the relationship between the number of orifices and the flow rates of pilot valves under different pressures.

FIG. 39 is a schematic cross section showing the surroundings of the orifices in FIG. 34.

FIG. 40 is a schematic cross section showing the state in which voltage has applied to the polymer actuator in FIG. 39.

FIG. 41 is a schematic cross section showing the average distance of polymer actuators when having been deformed.

FIG. 42 is a schematic cross section showing orifices disposed at different intervals.

FIG. 43 is a schematic cross section showing a further different example of the valve using the polymer actuator according to the present invention.

FIG. 44 is a partially enlarged view of FIG. 43.

FIG. 45 is a conceptual diagram of a flow rate measurement device using a pilot valve shown in FIG. 43.

FIG. 46 is a graph showing the relationship between the flow rate and the voltage.

FIG. 47 is a graph showing the voltage turned on and off and the flow rate.

FIG. 48 is a schematic cross section showing a further embodiment of the valve using the polymer actuator according to the present invention.

FIG. 49 is a schematic view showing the state in which a driving member in FIG. 48 has been bent upward.

### MODE FOR CARRYING OUT THE INVENTION

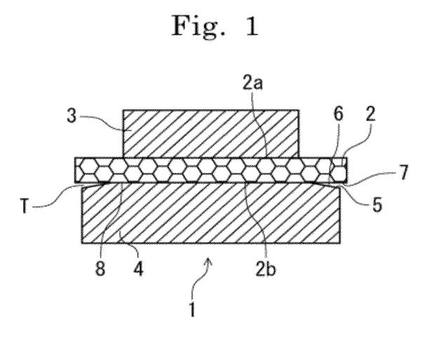

Embodiments of polymer actuators and valves using the polymer actuators according to the present invention will be described in detail hereinafter with reference to the drawings. FIG. 1 shows one embodiment of the polymer actuator according to the present invention, in which a main body of the polymer actuator (hereinafter referred to as the actuator body) 1 has a power driver 2 and fixed electrodes 3 and 4.

The power driver 2 is formed of an electrically stimulative polymer material deformable vial external electro stimuli. As the electrically stimulative polymer material, those that can be used for a dielectric elastomer actuator are raised and include polyurethane, silicone and nitrile rubber, for example. Furthermore, a polymer material having polyurethane added with additives including ion liquid and charge-transfer complex may be used as the power driver.

On the other hand, the fixed electrodes 3 and 4 may be formed of an appropriate conductor material, such as SUS304. The fixed electrodes 3 and 4 are disposed on an upper surface 2a and a lower surface 2b of the power driver 2, respectively, in an opposite manner and electrically connected respectively to the positive and negative electrodes of an external power source not shown. Thus, the fixed electrodes 3 and 4 can apply positive and negative external electro stimuli to the power driver in a planar fashion.

At least one of the upper and lower fixed electrodes 3 and 4, specifically the lower electrode 4 in the present embodiment, projects to the side, on which the power driver 2 is bent and deformed, and has an abutment surface 5 displaced by means of the Coulomb force when the power driver 2 has been deformed, thereby enabling the power driver 2 to come into contact with the power driver 2 and, at the time of application of no external electro stimuli, the abutment surface 5 forms a spaced-apart region T between itself and the power driver 2. The abutment surface 5 may be disposed on the upper and lower electrodes or on the upper electrode as described later. The abutment surface 5 is provided with an inclined surface 6 through which the abutment surface 5 and power driver 2 opposite to the abutment surface are relatively spaced apart gradually from each other and which has a circular-arc shape as shown in the drawing.

The power driver 2 has an opposite surface 7 opposite to the abutment surface 5. The abutment surface 5 is formed desirably to have surface roughness of 25 or more and, in this case, the responsiveness of the power driver to the voltage applied by the fixed electrodes 3 and 4 is heightened. On the other hand, since too large surface roughness necessitates higher applied voltage in the case of obtaining a corresponding amount of displacement, the surface roughness is preferably not more than 500. The surface roughness used herein indicates the center line average roughness.

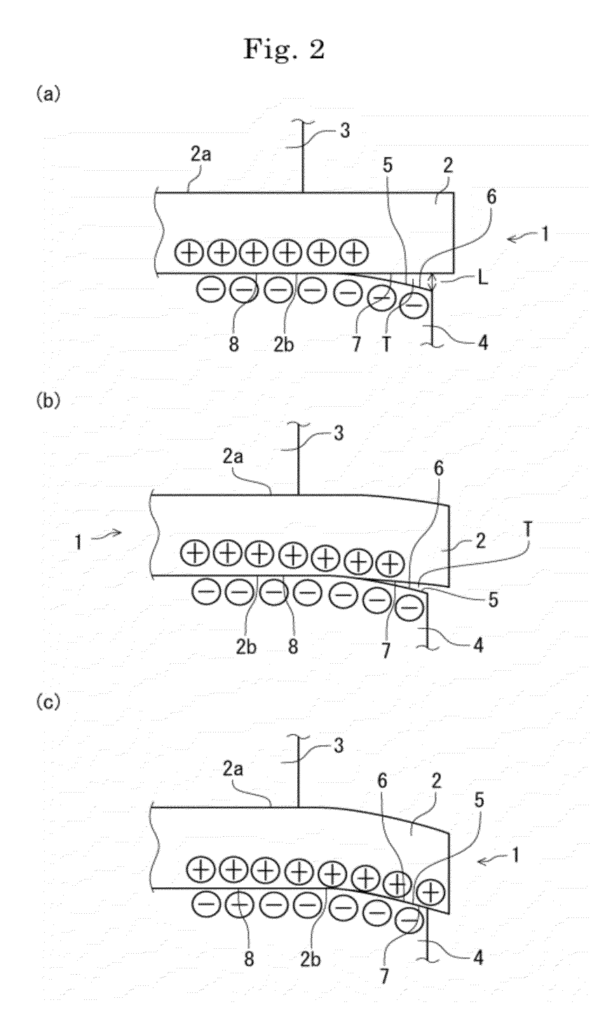

In the schematic views of FIG. 2, when voltage (electric field) has been applied to the fixed electrodes 3 and 4 of the actuator body 1, (1) a stress having electrical field vector distribution is generated in consequence of the fact that dielectric polyol or polyol having a dipole moment is oriented by the electric field to thereby change the structure of a polymer chain. At this time, (2) the Coulomb effect by the fixed electrodes 3 and 4 and the electric field therearound reduces the thickness-direction width of the power driver 2 to thereby swell the power driver 2 in the lengthwise planar direction at an angle of 90° relative to the thickness direction. In addition, (3) by means of the injection and eccentric location of the electrical charge, an asymmetric volume change is induced on both the electrode sides to generate a stress. Thus, the three stresses (1) to (3) are exerted on the power driver 2 to bend and deform the power driver 2 toward the lower fixed electrode 4.

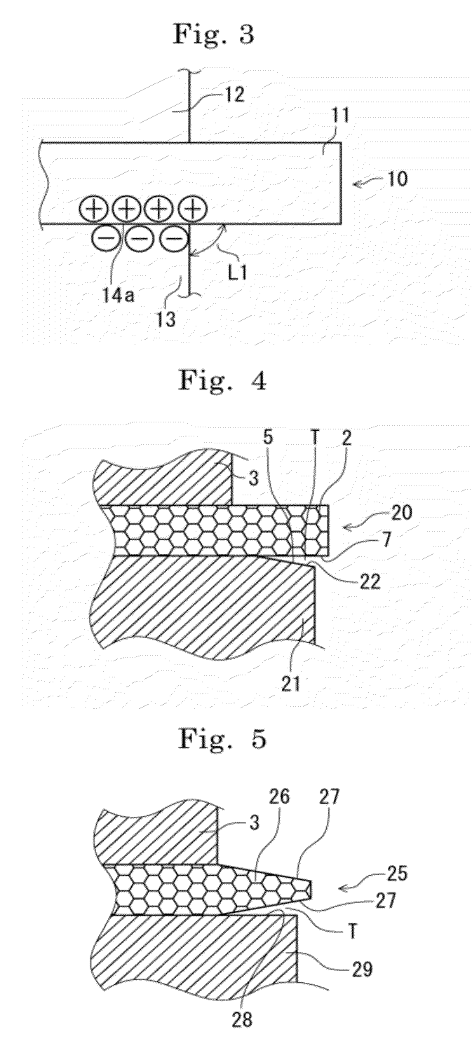

At that time, a distance L between the lower fixed electrode 4 and the power driver 2 as shown in FIG. 2(a) becomes shorter than a distance L1 shown in FIG. 3 showing an actuator member 10 by means of the abutment surface 5 formed in contact with the side on which the power drier 2 is deformed and, when voltage has been applied, large Coulomb force is induced between the power driver 2 and the fixed electrode 4 separate from the power driver 2 by negative charges collected on the electrodes and positive charges on the power driver. For this reason, the Coulomb force generated between the power driver 2 and the abutment surface 5 in the state close thereto at the distance L is added to the Coulomb force generated between the lower fixed electrode 4 and a fixed portion 8 to bend and deform the power driver 2 so as to come into contact with the abutment surface 5 as shown in FIG. 2(b) and FIG. 2(c). On the other hand, in the case of the actuator member 10 shown as the comparative example in FIG. 3, only the Coulomb force generated between an electrode portion 13 and a fixation portion 14a by the application of voltage to electrode portions 12 and 13 is exerted on a power driver 11. As a result, the amount of displacement of the power driver 2 is increased more than that of the power driver 11.

Furthermore, since the abutment surface 5 is provided with the inclined surface 6 through which the abutment surface 5 and power driver 2 are relatively spaced apart gradually from each other in the outer end direction, when the voltage to the fixed electrodes 3 and 4 has been increased, the power driver 2 is deformed while the distance L between the power driver 2 and the abutment surface 5 becomes shorter in an accelerated manner. At that moment, the force exerted among charged particles by the Coulomb force is inversely proportional to the square of the distance according to the Coulomb's law, and the power driver 2 is bent and deformed while exponentially increasing the Coulomb force between the power driver 2 and the abutting surface 5. In addition, when the distance between the power driver 2 and the fixed electrode 4 becomes small, positive charges of the power driver 2 are concentrated onto the negative electrode side to generate greater Coulomb force as described above, thereby increasing the amount of displacement. In consequence of these results, when part of the power driver 2 is in contact with the abutment surface 5, the Coulomb force at an approximate section is heightened to bend and deform the power driver 2 as adhering to the abutment surface 5. Since the exertion function of the charges are enhanced to deform the power driver 2 as being in contact with the abutment surface 5 in this way, the amount of displacement of the power driver 2 can be increased. Moreover, the formation of the surface 6 having the circular-arc shape on the abutment surface 5 causes the power driver 2 to be smoothly deformed.

As described above, the actuator body 1 has the simple structure having the power driver 2 and fixed electrodes 3 and 4 and is an actuator capable of being operated while securing high sealability through the bend and deformation of the power driver 2 by the external electro stimuli. At this time, since it is possible to greatly displace the power driver 2 with the small amount of applied voltage, it is possible to configure an actuator practically suitable for opening and closing of flow passages and for control of flow rate.

FIG. 4 shows the second embodiment of the polymer actuator according to the present invention. Incidentally, in this and the following embodiments, the same elements as those in the preceding embodiment are denoted by the same reference numerals, and the explanation thereof is omitted. An actuator body 20 in the present embodiment is provided with a lower fixed electrode 21 having an inclined surface 22 formed as a tapered surface. Also in this case, similarly to the previous case where the aforementioned inclined surface is formed as the circular-arc surface, it is possible to deform the power driver 2 and increase the amount of displacement of the power driver 2 with a small amount of applied voltage.

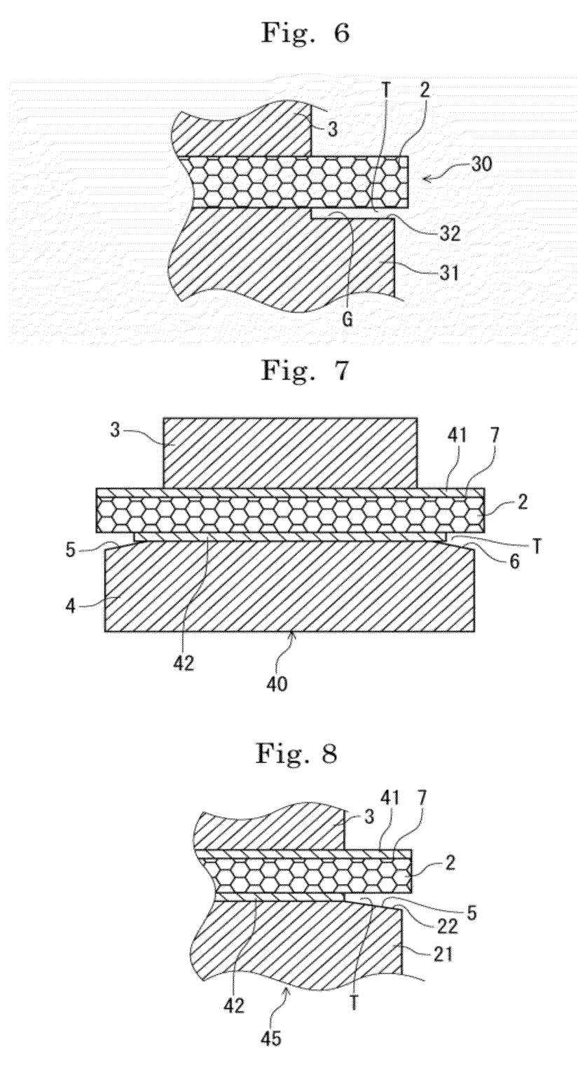

Shown in FIG. 5 is the third embodiment of the polymer actuator according to the present invention. An actuator body 25 in the present embodiment is provided with a power driver 26 having upper and lower inclined surfaces 27 and 27 formed as tapered surfaces. Also in this case, similarly to the case where the fixed electrodes are formed with the inclined surfaces, it is possible to increase the amount of displacement of the power driver 26 with a small amount of applied voltage. Thus, the inclined surface may be formed on either the abutment surface in the spaced-apart region T or the power driver opposite to the abutment surface. Otherwise, it may be formed on both the abutment surface and the power driver and, in this case, the inclined surface may be formed in various shapes including a circular-arc shape, radiation shape and tapered shape insofar as the abutment surface and the power driver are gradually spaced apart relatively from each other in the outer end direction. In addition, while the inclined surface 27 is formed on the upper and lower surfaces of the power driver 26 in the present embodiment, it may be formed only on a lower fixed electrode 29 having an abutment surface 28.

FIG. 6 shows the fourth embodiment of the polymer actuator according to the present invention. An actuator body 30 in the present embodiment has a lower electrode 31 provided with an abutment surface 32 and has the spaced-apart region T formed therein with a stepped region G for separating the power driver 2 in the state of application of no voltage. Also in this case, the Coulomb force between the power driver 2 and the fixed electrode 31 is increased through the stepped region G to increase the amount of deformation of the power driver 2 with a small amount of applied voltage. The stepped region G may be formed on one or both of the abutment surface and the power driver in the spaced-apart region T. Besides the stepped region shown in the drawing, it may be formed on the side of the power driver 2. It is unnecessary to subject the stepped region to highly accurate processing insofar as it can maintain the spaced-apart state between the power driver and the abutment surface in the state of application of no voltage.

The fifth embodiment of the polymer actuator according to the present invention is shown in FIG. 7. An actuator body 40 in the present embodiment has flexible electrodes 41 and 42 in addition to the power driver 2 and fixed electrodes 3 and 4. The power driver 2 and fixed electrodes 3 and 4 may be formed of the same material as described above, and the lower fixed electrode 4 is formed with the inclined surface 6 having the circular-arc shape. The flexible electrodes 41 and 42 are formed of an appropriate conductive material. A gold material is used, for example, to form a gold thin film on the power driver 2 by sputtering. The flexible electrode 41 is disposed on the surface (opposite surface 7) opposite to the abutment surface 5 and designed to be deformed together with the power driver 2 through application of external electro stimuli to the power driver 2.

Thus, the actuator body 40 has the flexible electrodes 41 and 42 vapor-deposited on the power driver to obtain different voltage application regions, by means of which the distribution of stress induced in the power driver 2 is eccentrically located in one of the positive and negative electrodes, and is configured to have electric field distribution so as to bend and deform the power driver 2 to the side having no opposite application region, i.e. on the side of the fixed electrode 4. As a result, it is possible to exponentially enhance the applied voltage as compared with the case provided with no flexible electrode and to further increase the amount of displacement of the power driver 2.

FIG. 8 shows the sixth embodiment of the polymer actuator according to the present invention. In an actuator body 45 of the present embodiment, the power driver 2 has the flexible electrodes 41 and 42 vapor-deposited thereon by sputtering. Of the fixed electrodes 3 and 21, the lower fixed electrode is formed with the inclined surface 22 having the tapered shape. Thus, also in the case of providing the flexible electrodes 41 and 42, it is possible to provide the inclined surface 22 having an appropriate shape.

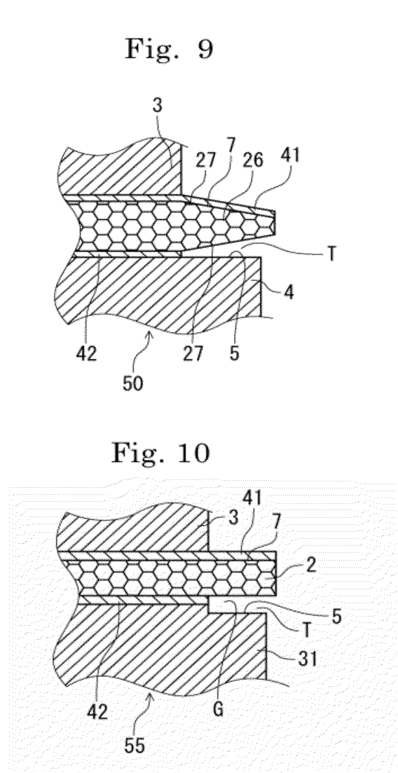

Shown in FIG. 9 is the seventh embodiment of the polymer actuator according to the present invention. In an actuator body 50 of this embodiment, the power driver 26 is provided on the upper and lower surfaces thereof with the inclined surfaces 27 having the tapered shape. The flexible electrode 41 deformed together with the power driver 26 is formed on the opposite surface of the abutting surface 5, and the flexible electrode 42 is formed between the power driver 26 and the fixed electrode 4.

The eighth embodiment of the polymer actuator according to the present invention is shown in FIG. 10. In an actuator body 55 of this embodiment, the stepped region G for separating the power driver 2 in the state of application of no voltage is provided in the spaced-apart region T and, moreover, the flexible electrodes 41 and 42 are provided between the power driver 2 and the opposite surface 7 opposite to the surface of the abutment surface 5 of the power driver 2 and between the opposite surface and the fixed electrode 31. In this case, it is possible to increase the amount of displacement of the power driver 2 more than in the case of providing no flexible electrode.

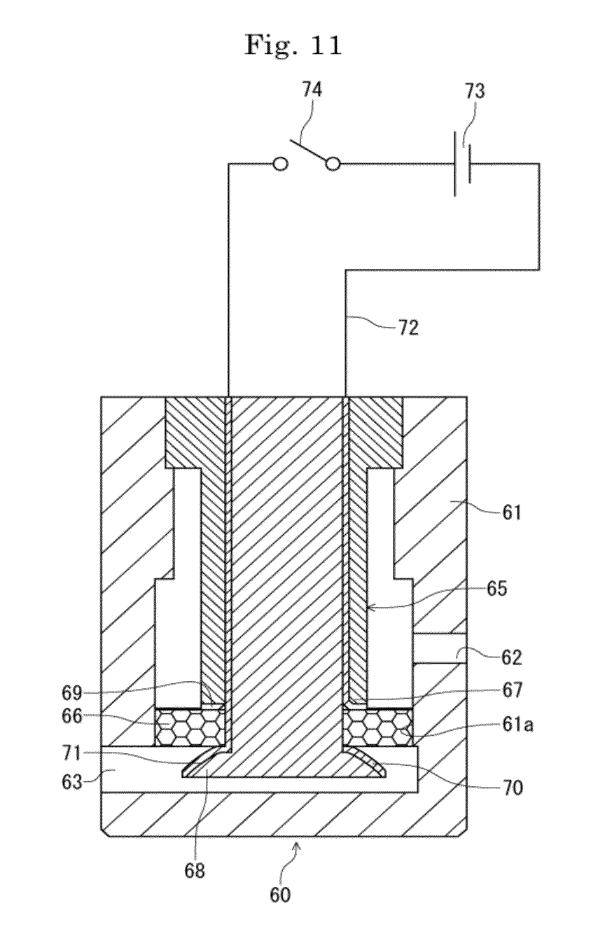

A valve using the polymer actuator according to the present invention will be described subsequently. FIG. 11 shows an embodiment of the valve using the polymer actuator according to the present invention. A valve body 60 has a body 61 provided with plural flow passages comprising an entrance-side flow passage 62 and an exit-side flow passage 63, and an actuator body 65 is disposed as a valving element in the body 61.

The actuator body 65 has a power driver 66, upper and lower fixed electrodes 67 and 68 and flexible electrodes 69 and 70, and the lower fixed electrode 68 is formed with an inclined surface 71 having a circular-arc surface. A power circuit 72 is connected to the electrodes 67 and 68 and provided with a power source 73 and a switch 74. With this structure, the operation of the actuator body 65 causes the flow passages 62 and 63 to be opened and close and the flow rate to be controlled.

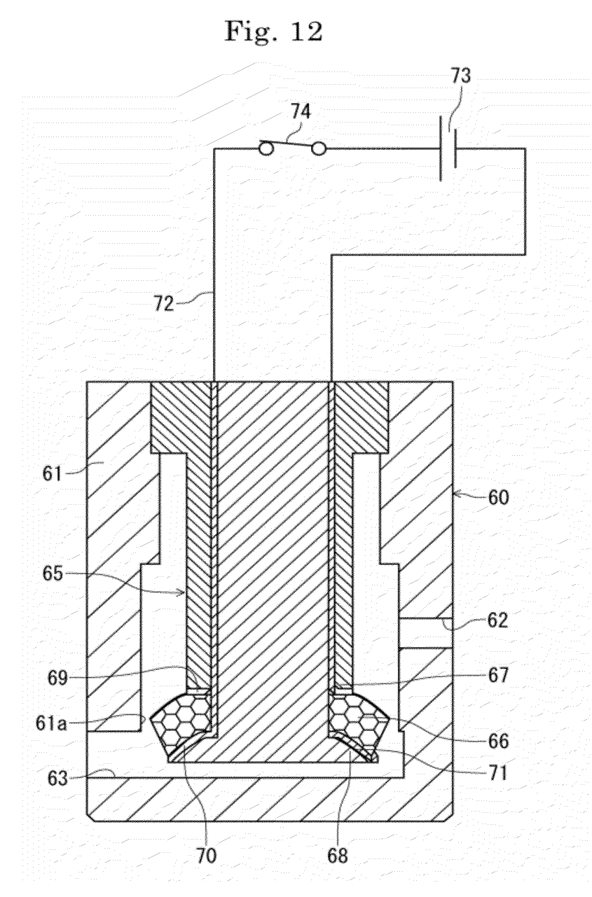

FIG. 11 shows a state in which the switch 74 is turned off and, in this case, the power driver 66 comes into contact with a seat surface 61a formed in the body 61 to bring the flow passage to a closed state. On the other hand, FIG. 12 shows a state in which a switch 75 is turned on and, in this case, voltage is applied to the power driver 66 and the power driver 66 is bent and deformed to depart from the seat surface 61a to cause the entrance-side flow passage 62 and the exit-side flow passage 63 to communicate with each other, thereby bringing the flow passages to an open state. Since the valve body 60 has a structure in which use of the actuator body 65 controls opening and closing the flow passages, its entirety is made simple and compact. The valve body 60 in the present embodiment is in a valve-closed state when the switch 74 has been turned off, thus constituting a so-called normally closed type valve. However, it may be configured as a normally open type valve by bringing it to a valve-open state when the switch 74 has been turned off.

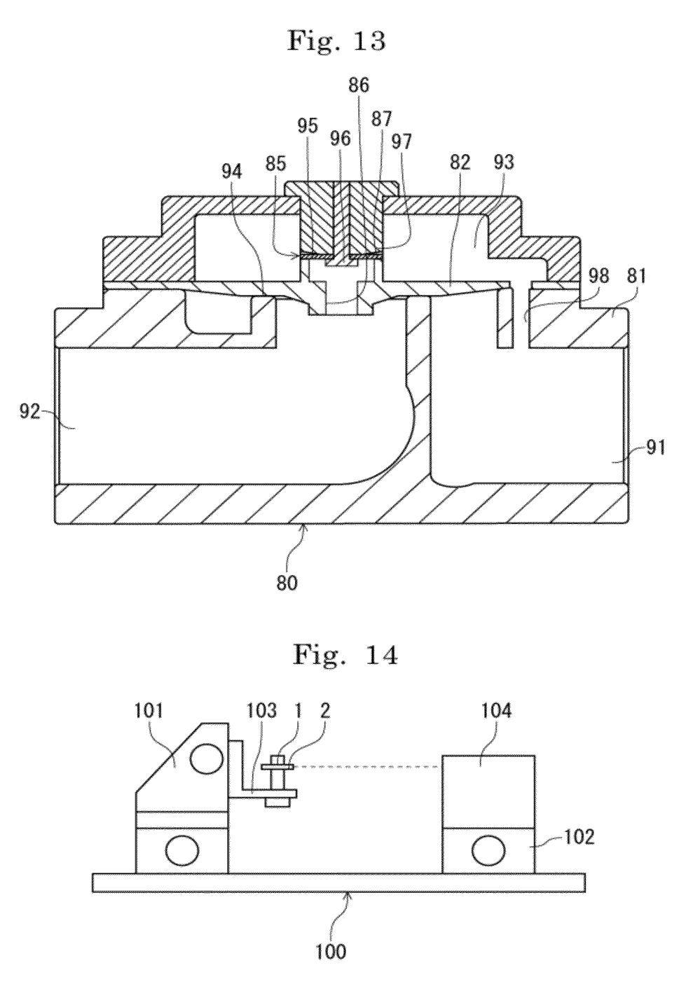

FIG. 13 shows another embodiment of the valve using the polymer actuator according to the present invention, and the polymer actuator is built in a valve body 80. The valve body 80 in the present embodiment has a body 81, a diaphragm valving element 82 and an actuator body 85.

Formed inside the body 81 are a primary-side flow passage 91 and a secondary-side flow passage 92 between which a connection flow passage 93 is formed to connect these flow passages 91 and 92. The connection flow passage 93 communicates with the primary-side flow passage 91 via a communication passage 98, and the diaphragm valving element 82 that is a valving element for opening and closing the flow passages is provided between the connection flow passage 93 and the secondary-side flow passage 92. The diaphragm valving element 82 can be seated on a valve seat 94 formed within the body 81 and is provided therein with a through-hole 86 via which the connection flow passage 93 and the secondary-side flow passage 92 are allowed to communicate with each other. Furthermore, the through-hole 86 is provided on the upper end face thereof with a valve seat portion 87.

The actuator body 85 has a power driver 95 and fixed electrodes 96 and 97 and is disposed on the upper side of the diaphragm valving element 82. The power driver 95 is attached to the upper surface of the valve seat portion 87 of the diaphragm valving element 82, and the on-off operation of a power source not shown for applying voltage to the fixed electrodes 96 and 97 enables the valve seat portion 87 to be opened and closed. Thus, by disposing the actuator body 85 within the flow rate of the valve body 80 and operating the actuator body 85 as a pilot valve, it is possible to control the valve body 80 to be opened and closed.

FIG. 13 shows an off state of the power source and, in this case, the primary-side flow passage 91 and connection flow passage 93 are held under the same pressure via a communication valve 98 and, therefore, the diaphragm valving element 82 is seated on the valve seat 94 by the pressure from the primary-side flow passage 91 to bring the connection flow passage 93 and secondary-side flow passage 92 to a closed state. When the power source is turned on from this state to apply voltage to the fixed electrode, the outer periphery of the power driver 95 departs from the valve seat portion 87 and is bent and deformed as coming into contact with the fixed electrode 97. As a result, the connection flow passage 93 and secondary-side flow passage 92 are allowed to communicate with each other via the through-hole 86, thereby enabling a fluid to flow from the primary-side flow passage 91 to the secondary-side flow passage 92.

When the actuator body 85 is built as a pilot valve in the valve body 80, as described above, the actuator body 85 is operated with a small amount of applied voltage while attaining its entire miniaturization to enable opening and closing of the valve body 80 to be controlled with high accuracy. Since a conventionally known pilot valve is an electromagnetic valve comprising a solenoid coil, an iron core and a coil irrespective of it being an inside pilot valve that uses an operation pressure fluid split from a fluid on the primary side or an outside pilot valve that supplies the operation pressure fluid from the outside, it has been installed as a separate structure from a valve in the main circuit. However, by causing the polymer actuator to fulfill the same function as the solenoid of the electromagnetic valve, it is possible to reduce the number of component parts, provide its structure integral with the main circuit through the actuator body built in the valve body as shown in the same figure and consequently provide a low-cost and further compact substituting article having a merit of being easy to assemble. The actuator body can be built in each of other various kinds of valve bodies than the valve body 80 in the present embodiment and, also in this case, it is possible to perform highly accurate opening and closing control or flow rate control with a small amount of applied voltage.

The air having pressure of 2.8 kPa was supplied to the valve of this structure. As a result, when the leakage quantity of air in the closed state of the diaphragm valving element was controlled to 1 ml/min or less and voltage of 0.75 kV was applied to bring the diaphragm to an open state, it was possible to ensure the flow rate of about 600 ml/min. On the other hand, in the actuator using the fixed electrodes having the conventional structure, even the application of twice voltage of 1.5 kV resulted in the flow rate kept at 1 ml/min, failing to confirm any variation, and in the diaphragm valving element kept in closed state. In this way, it was confirmed that the polymer actuator of the present invention could sufficiently fulfill the function of a pilot valve for controlling small flow rate.

Next, the prescribed voltage was applied to the polymer actuator of the present invention to measure the amounts of displacement thereof through the experiments. In the measurements of the amounts of displacement, a displacement measurement device shown in FIG. 14 was used. The displacement measurement device 100 has right and left movable tables 102 and 101, one of the movable tables 101 is provided with a fixing portion 103 to which the actuator body 1 can be fixed, and the other movable table 102 is provided with a laser displacement gauge (manufactured by Keyence Corporation under model designation of LJ-G080) 104. The laser displacement gauge 104 irradiates laser beams L onto the actuator body 1 to enable the amounts of bend and displacement of the power driver 2 to be measured.

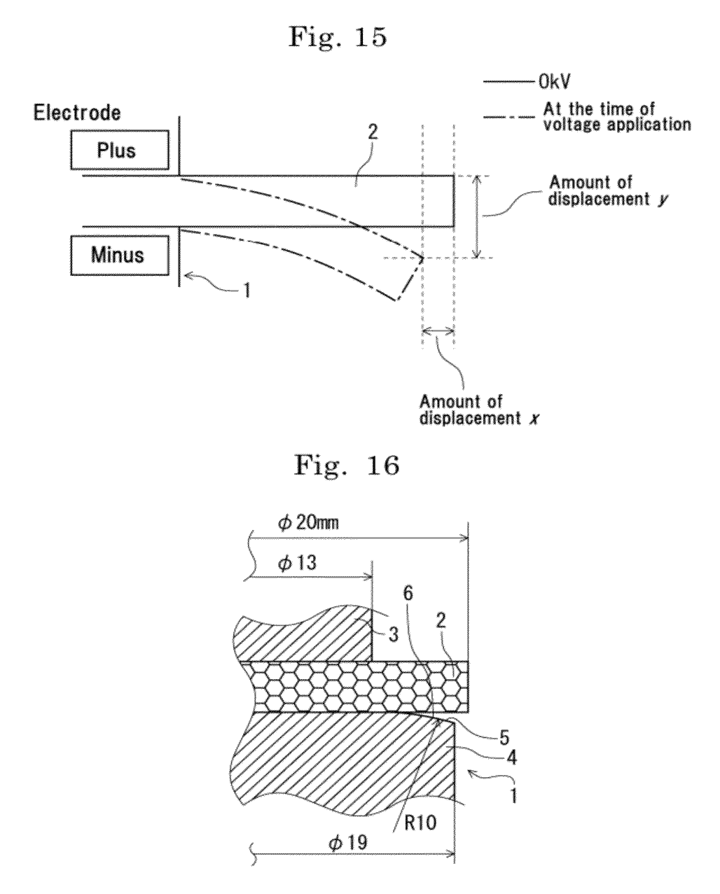

In the case of measuring the amounts of bend and displacement of the actuator body 1 using the laser displacement gauge 104, though the amounts of displacement x and y as shown in FIG. 15 were conceivable as those of the bent-type power driver 2, since the amount of displacement y was larger than the amount of displacement x and was difficult to affect by the measurement error, the amount of displacement y was measured, with the amount of displacement y defined as the amount of displacement of the actuator body 1. In this case, it is noted that the upper side of the actuator body is set as a plus side and the lower side thereof as a minus side, that the amount of displacement is expressed as plus in the case of the displacement toward the plus side, and that the amount of displacement is expressed as minus when the displacement has been toward the minus side.

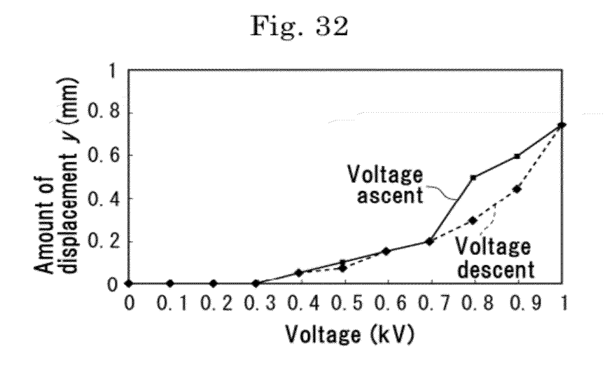

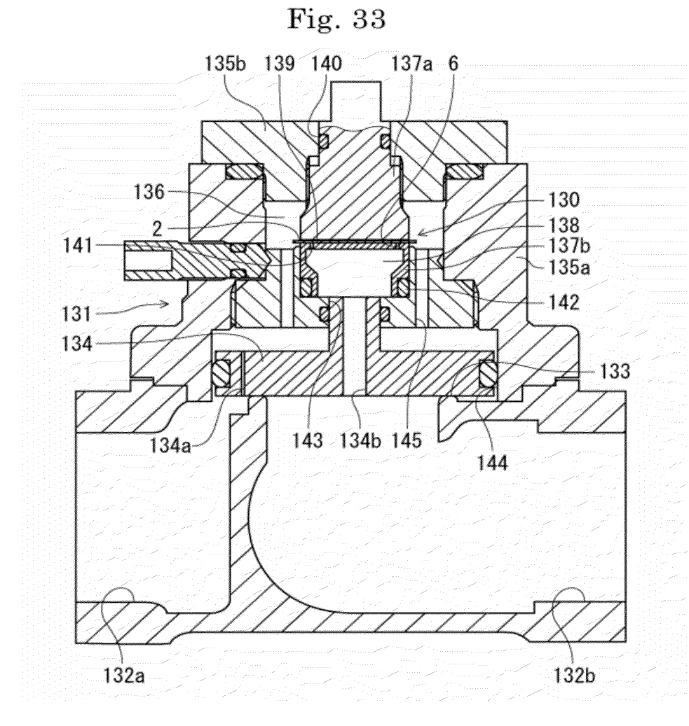

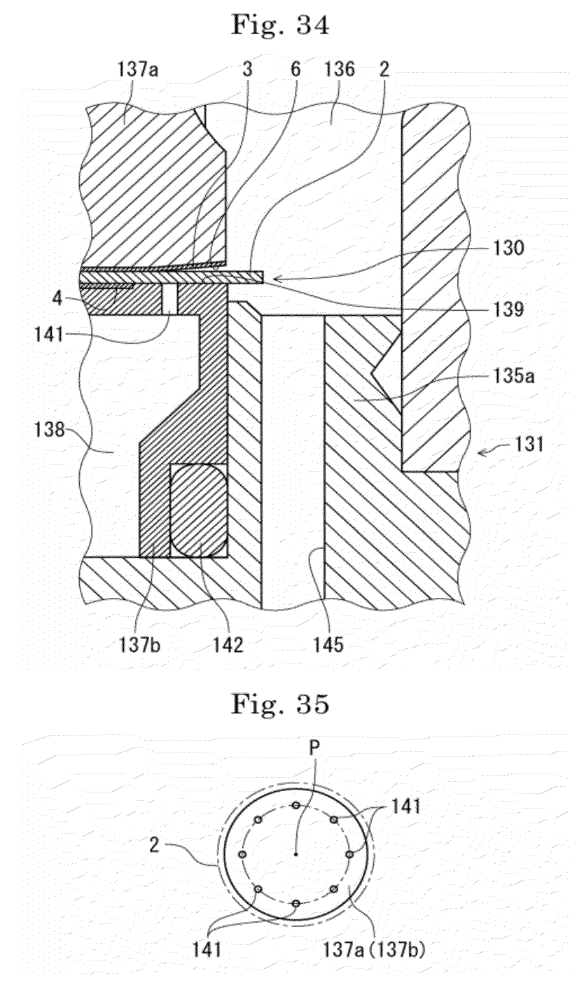

Next, FIG. 33 is a cross section showing still another embodiment of the valve using the pilot valve, FIG. 34 is a partially enlarged view of FIG. 33, and FIG. 35 is a schematic view showing orifices in FIG. 33. Here, in the case of configure a pilot valve using the polymer actuator, since generated stress in the polymer actuator is smaller than that of a driving solenoid in a general pilot valve, the pilot valve using the polymer actuator poses a problem in difficulty in controlling the same pressure and flow rate as those of the pilot valve using the solenoid. Furthermore, it is also easy to be inferior in durability and response speed to the general pilot valve. In the pilot valve of FIG. 33, it is intended to solve these problems.

FIG. 33 shows a valve 131 provided therein with a pilot valve. The valve 131 has the pilot valve 130, a primary-side flow passage 132a and a secondary-side flow passage 132b, and an annular valve seat 133 provided therebetween. The annular valve seat 133 has a piston-type main valve 134 capable of being seated thereon. Thus, in this valve 131, the power driver 2 of the polymer actuator functions as the pilot valve 130 for opening and closing the piston-type main valve 134. In this case, even in the case of the main valve 134 being of a diaphragm type, it is similarly possible to configure a valve. In addition, while the pilot valve 130 is used for opening and closing the piston-type main valve 134 in the present embodiment, the pilot valve 130 can also used as a single body.

In the case of using the valve as the single body, for example, a fluid having low viscosity is advantageous as the fluid to be used and, particularly, a gas fluid such as air is advantageous. Furthermore, the valve can suitably be used as an on-off valve for controlling these fluids and a valve for adjustment of the flow rate. Moreover it can secure plenty of flow rates through an increase in the number of orifices disposed at the prescribe pitch, suitably be used in the factory piping or machinery equipment, and be driven with a small amount of consumed power by the used thereof as an electromagnetic valve particularly for driving a cylinder.

The pilot valve 130 is stored in a storage chamber 136 formed in the valve 131 and surrounded by a cover 135a and a cap 135b of the valve. The storage chamber 136 communicates with the primary-side flow passage 132a via a through-bore 134a to be described later. Since the valve 131 has the pilot valve 130 of the present embodiment, it can be utilized for an application requiring large flow rate. The pilot valve 130 may disposed outside the valve 131.

The pilot valve 130 in the valve 131 comprises the power driver 2 having a flexible electrode not shown, the fixed electrode 3 disposed along the inclined surface 6 and the corresponding fixed electrode 4 to constitute the polymer actuator. The power driver 2 is formed between the fixed electrodes 3 and 4, and the fixed electrodes 3 and 4 are formed on a first power driver holder 137a and a second power driver holder 137b, respectively. The fixed electrodes 3 and 4 are connected to a power source not shown. The power source applies voltage to the power driver 2 via the fixed electrodes 3 and 4.

While the fixed electrodes 3 and 4 in the present embodiment are formed on the first power driver holder 137a and second power driver holder 137b as separate bodies, the fixed electrodes may be formed integrally on the first and second power driver holders 137a and 137b, respectively. Thus, each fixed electrode can be formed on each power driver holder as a separate or integral body.

Since the pilot valve 130 operated by the polymer actuator is incorporated into the valve 131, the entire structure is made compact. In addition, since the plate-like power driver is operated relative to plural small orifices to control the pressure, the height of the pilot valve 130 can be lowered to enable the valve 131 to be further miniaturized.

As shown in FIG. 33, the first power driver holder 137a is formed in the shape of a substantially circular cylinder and has the bottom surface provided with the inclined surface 6. The fixed electrode 3 is formed on the inclined surface 6, and the power driver 2 is deformed along the inclined surface 6 at the time of voltage application. The first power driver holder 137a is screw-fitted in the cap 135b with an O-ring 140 so as to be movable up and down and, thus, the height of the inclined surface 6 can be adjusted relative to the power driver 2.

The second power driver holder 137b is formed in a cylindrical shape and provided on the upper surface thereof with a valve seat portion 139 on which the power driver 2 is seated and with the fixed electrode 4. Plural orifices 141 are bored in the circumference of the valve seat portion 139 and formed to communicate with a secondary-side communication passage 138 formed inside the second power driver holder 137b. The second power driver holder 137b is fixed to the cover 135a via an O-ring 142 and, after the fixation of the second power driver holder, the primary side and the secondary side of the pilot valve 130 are allowed to communicate with each other via the orifices 141.

As shown in FIG. 35, the orifices 141 are radially formed equidistantly from a center P and, when the orifices have a diameter of 0.5 mm, for example, the number of the orifices are 2 to 8. In the figure, the outside diameter of the power driver 2 is larger than that of the orifices 141 and the first power driver holder 137a (second power driver holder 137b). As a result, the power driver 2 blocks up the valve seat portion 139 to stop up the orifices 141 with exactitude. Therefore, at the time of application of voltage, the power driver 2 is deformed along the inclined surface 6 to exactly form a communication flow passage in the presence of the orifices 141.

The main valve 134 assumes a substantially circular disc shape and is attached an insertion hole 143 formed in the cover 135a so as to be movable up and down. A spatial guide portion 144 is formed inside the cover 135a, and the main valve 134 moves up and down while being guided by the guide portion 144. For this reason, the main valve 134 is difficult to dispose at a different center by the operation of the liquid. The main valve 134 is provided at the central section thereof with a vent hole 134b communicating with the orifices 141 and with the through-bore 134a at a position further close to the outer periphery from the annular valve seat 133.

In the valve 131, the power driver 2 of the pilot valve 130 is operated by application or stop of application of voltage from the fixed electrodes 3 and 4 and, through opening or closing of the valve seat portion 139 by means of the power driver 2, the orifices 141 are brought to a communication state or closed state to manifest the function of the pilot valve. The pilot valve 130 is of a normally closed type in which the power driver 2 is open-operated when the voltage has been applied.

In FIG. 33 and FIG. 34, when the application of voltage has been stopped to bring the pilot valve 130 to a closed state, the orifices 141 are closed by the power driver 2 to allow the primary-side flow passage 132a to communicate with the through-bore 134a, a bore portion 145 formed in the cover 135a and the storage chamber 136 and, as a result, the secondary-side flow passage 132b is in a state communicating with the vent hole 134b. At this time, since the area of the upper side (primary side) of the main valve 134 receiving the pressure is larger than that of the lower side (secondary side), the main valve 134 is thrust against the annular valve seat 133. With this motion, the primary-side flow passage 132a and the secondary-side flow passage 132b are closed.

Subsequently, in the case of the pilot valve 130 having been in an open state through the deformation of the power driver 2 by the application of voltage to the fixed electrodes, since the pressure in the storage chamber is released to the secondary-side flow passage 132b via the orifices 141 and vent hole 134b, the main valve 134 receives the pressure from the lower side, thereby pushing the main valve 134 along the guide portion 144 by means of the primary-side pressure. For this reason, the main valve 134 is separated from the annular valve seat 133 to supply the fluid from the primary-side flow passage 132a to the secondary-side flow passage 132b.

At this time, assuming that the flow rate of the through-bore 134a is Q1 and that the total flow rate of the orifices 141 of the valve seat portion 139 is Q2 as conditions for allowing the pilot valve 130 to function as a valve, when the flow rate Q2 is not larger than the flow rate Q1, since no pressure difference occurs between the upper side and the lower side of the main valve 134, it is impossible to allow the main valve 134 to function as a pilot valve. In addition, closing response speed is greatly affected by the flow rate Q1, and opening response speed is affected by the difference between the flow rate Q2 and the flow rate Q1. For this reason, the flow rate Q2 is made larger to enable the opening and closing response speeds to be set in a wide range.

In this valve 131, since the inside of the second power driver holder 137b is formed integrally with the communication passage 138 as shown in the drawing, increasing the number of the orifices 141 open to the upper surface of the valve seat portion 139 enables the flow rate to be increased. In addition, owing to this integration, the flow rate toward the secondary-side flow passage 132b can be increased while reducing pressure loss. When the diameter of the orifices 141 is made small and plural orifices are provided, the opening and closing operation can smoothly be performed even under high pressure.

Since the valve 131 is configured as described above, by decreasing the diameter of the orifices of the pilot valve 130, the stress generated in the polymer actuator can act efficiently on the pressure load. For this reason, it is possible to secure large flow rate of high pressure at the time of driving the pilot valve 130.

The pressure and flow rate on the primary side of the pilot valve 130 were measured with a manometer and a flowmeter, both not shown, were connected to the primary side when voltage was applied to operate the power driver while changing the number and bore diameter of the orifices and changing the pressure. In this case, only the pilot valve portion was designated a target to be measured in pressure and flow rate, and a mechanism composed only of the pilot valve 130 was provided in order not to be affected by the pressure and flow rate resulting from the action of the main valve 134 of the valve 131. The pressure and flow rate of the pilot valve mechanism were measured.

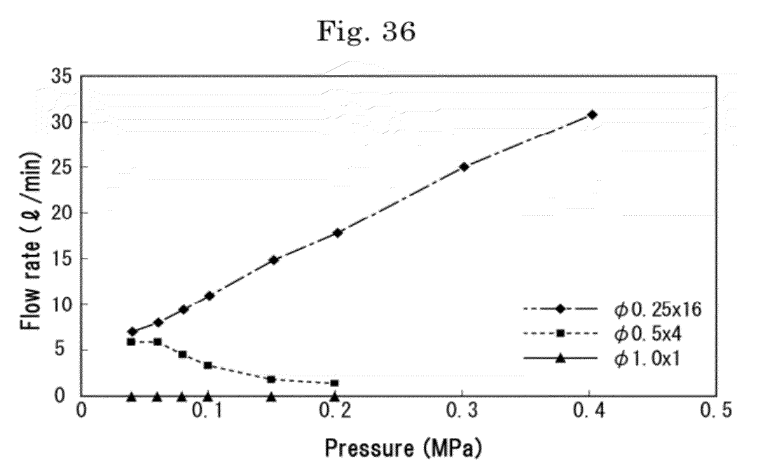

The flow rate and pressure were measured when the total flow passage area of the orifices 141 of the pilot valve is made constant and the diameter of the orifices formed in the same circumference (14 mm in diameter) was changed to 1.0, 0.5 and 0.25 mm. The results of the measurement are shown in FIG. 36. At this time, the conditions of the polymer actuator were that the power driver was formed of ester polyurethane having a thickness of 0.5 mm, that the drive voltage was 1.5 kV and that an inclined electrode having the shape shown in FIG. 33 was used. The flow rate was measured in 10 seconds from the application of the voltage.

As the total flow passage area of the orifices 141, one orifice having a diameter of 1.0 mm was set as the standard to dispose four orifices having a diameter of 0.5 mm and 16 orifices having a diameter of 0.25 mm. Since the total flow passage area in respect of the orifices as described above was made constant, the theoretical flow rates ought to be substantially the same even in consideration of the pressure loss. However, the results of the actual measurement shown in FIG. 36 were greatly different. It was found that when the total flow passage area of the orifices was made constant, it was possible to provide a pilot valve of higher pressure and large flow rate through further reduction in diameter of the orifices.

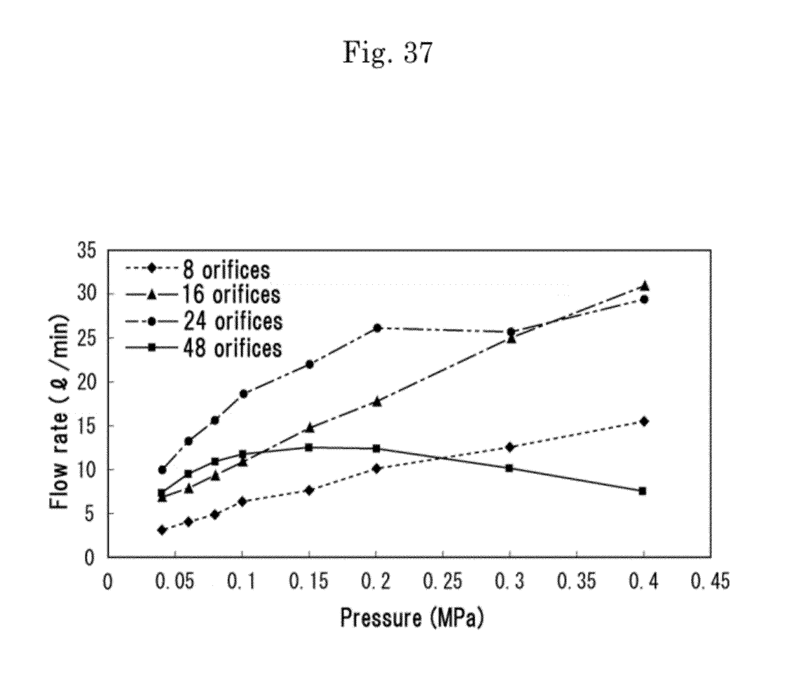

Next, the relationships between the pressure and flow rate at the time of disposing the orifices 141 having a diameter of 0.25 mm on the same circumference (14 mm in diameter) were measured, with the number of the orifices 141 changed to 8, 16, 24 and 48. The results of the measurement are shown in FIG. 37. In the figure, the comparison between the case of 8 orifices and the case of 16 orifices revealed that the flow rate under each pressure in the case of 16 orifices was substantially twice that in the case of 8 orifices to confirm the rational relationship.

When comparing the case of 16 orifices with the case of 48 orifices, however, it was rational that the flow rate of the latter case be three times that of the former case. However, the actual result showed that the flow rate of the latter case fell below the three times. In addition, in the case of 24 orifices, the corresponding graph in the drawing had a small inclination, with the pressure of 0.2 MPa as a turning point. This is because the stress generated in the polymer actuator is larger than the pressure load under the pressure of 0.2 MPa or less and because the generated stress is antagonistic to the pressure load under the pressure of 0.3 MPa or more.

It was understood from FIG. 37 that the increase of the number of the orifices having the same diameter did not always bring about an increase in flow rate. It could be confirmed from the same figure that 16 or less orifices 141 under the pressure of 0.4 MPa or more might be disposed in concert with the required flow rate and that 24 or less orifices 141 under the pressure of 0.2 MPa might be disposed in conformity to the required flow rate. It was further confirmed that in the case of disposing the orifices 141 on circumferences having different diameters, straight line or any other shape, the centers of the two orifices under the pressure of 0.4 MPa or more might have a distance of 2.7 mm or more, for example and that the distance at the pressure of 0.2 MPa or less might be 1.8 mm or more, for example.

As regards orifices having a diameter of 0.5 mm, the desirable number of orifices disposed on the same circumference (14 mm in diameter) to which the fluid flowed at the maximum flow rate under different pressures (0.1, 0.08 and 0.06 MPa) was examined. The results of the measurement of the flow rates under different pressures are shown in FIG. 38. In this case, it was found that the maximum flow rate was acquired under the pressure of 0.08 MPa when the number of orifices was 8 and that the large flow rate was obtained under the pressure of 0.06 MPa when the number of orifices was 16. It was confirmed from these findings that in the case of the orifices having a relatively large diameter of 0.5 mm, the flow rates tended to become lower when the pressure became high and that the increased number of orifices could not always increase the flow rate.

It was confirmed that in the case of disposing the orifices on circumferences having different diameters, straight line or other shapes, the centers of two orifices 141 under the pressure of 0.08 MPa or more might have a distance of 5.5 mm or more, for example, and those under pressure of 0.06 MPa might have a distance of 2.7 mm or more, for example.

Subsequently, in assembling in a valve a pilot valve of a type driving a polymer actuator (power driver) via orifices to control pressure and flow rate, the diameter of and the interval between the orifices suitable for the pilot valve are studied in consideration of the aforementioned results of measurement. On this study, the diameter of and the interval between the orifices limited when the orifices cannot be brought to an open state by the power driver in the case of having exerted load of prescribed pressure onto the inside of the pilot valve, will be described.

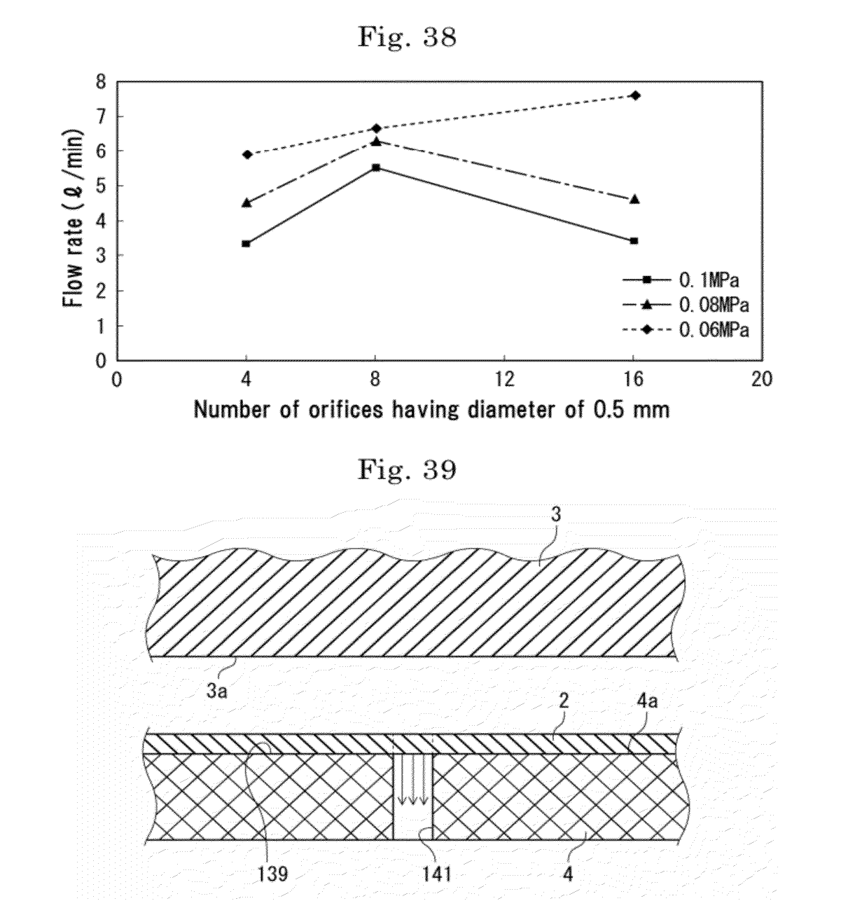

First, the affection of the diameter of the orifices on the motion of the power driver will be described. FIG. 39 schematically shows the periphery of the orifices 141 in FIG. 34, no voltage is applied to the power driver 2 of the pilot valve 130, and the state in which the orifices 141 are closed by the power driver is shown. In such a state of disabling opening of the orifices 141, the relationship between the stress generated in the polymer actuator and the pressure load inside the storage chamber 136 in FIG. 34 is expressed as Generated stress in polymer actuator<Pressure load (Formula 1).

At this moment, the inside of the storage chamber 136 is filled with prescribed pressure, and the pressure of the secondary-side flow passage 132b becomes zero. In the case of the pressure of the secondary-side flow passage 132b being not zero, pressure P1 applied to the power driver 2 in a region sandwiched between the storage chamber 136 and the orifice 141 shown by arrows in FIG. 39 becomes pressure difference between the storage chamber 136 and the secondary-side flow passage 132b.

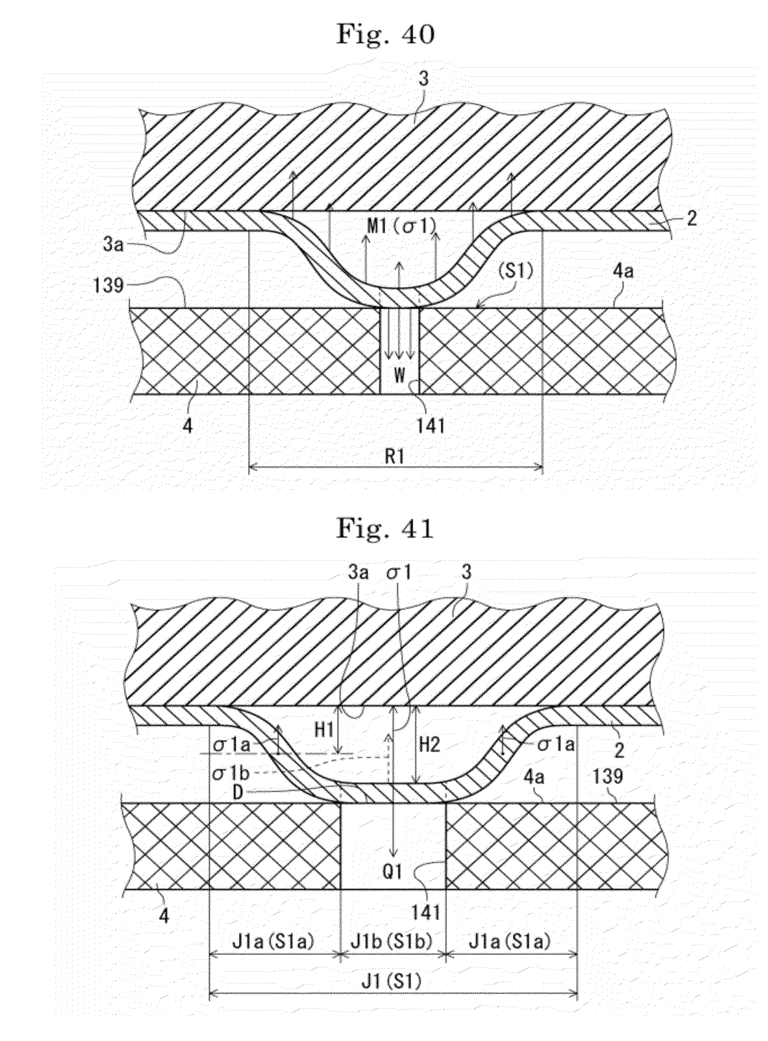

FIG. 40 shows a case in which the state of (Formula 1) is maintained when prescribed voltage has been applied to the polymer actuator in FIG. 39 and the pilot valve 130 is not operated until its closed state. Here, a force M1 is a product of an area S1 in a deformation region R1 and generated stress of shown by upward arrows in the area S1 in the deformation region R1 at the time of voltage application relative to a pressure load W shown by downward arrows in FIG. 40. The area S1 in the deformation region R1 is an area of the power driver 2 around the orifices 141 not in contact with abutment surfaces 3a and 4a of the fixed electrodes 3 and 4. It is clear that the generated stress in the portion of the power driver 2 in contact with the abutment surfaces 3a and 4a does not act on the pressure load W.

As regards the portion of the power driver 2 onto which the pressure load W is exerted, only downward pressure load is exerted onto the portion of the power driver in close contact with the orifices 141. In the state of (Formula 1), the power driver 2 on the orifices 141 becomes a fixed section, and other portion than the fixed portion assumes a state close to the free end portion and a state of fulfilling the elastic force by the generated stress σ1. In this case, stress toward the abutment surface 3a is exerted onto the free end portion of the power driver 2 at the time of voltage application and, as shown in FIG. 40, the power driver 2 becomes sticking to the abutting surface 3a.

In this state, assuming that the generated stress exerted onto the free end portion of the power driver 2 is designated as σ1, that the area in a distance J1 in the deformation region R1 on which load of the generate stress σ1 acts is designated as S1, that the pressure applied to the orifices 141 as P1, that the area of the orifices to which the pressure P1 is applied as D and that these are substituted into (Formula 1), the relationship obtained when the pilot valve 130 is not an open state is expressed as Generated stress σ1×Area S1<Pressure P×Orifice area D (Formula 2).

The generated stress σ1 acts on, of the area S1, an area S1b at a distance J1b of a portion of the power driver 2 on the orifices 141 shown in FIG. 41, which portion becomes flat, and an area S1a at a distance J1a of a portion of the power driver 2 around the area S1b, which portion inclines. When the portion of the orifices on which the generated stress σ1 has been divided into the area S1a and area S1b, forces by the generated stress σ1 act on the respective areas via average distances H1 and H2.

At this time, as shown in FIG. 41, the average distance H2 corresponds to a distance from the abutment surface 3a to the flat portion of the power driver 2, the average distance H1 corresponds to a distance from the abutment surface 3a to the inclined portion of the power driver 2, and the average distance H1 is substantially ½ of the average distance H2. That is to say, the relationship of the average distance H2>the average distance H1 is satisfied. Assuming that the generated stress exerted on the flat portion of the power driver 2 is denoted by σ1b and that the generated stress exerted on the inclined surface by σ1a, since force exerted between charged particles is inversely proportional to the square of the distance according to the Coulomb's law, the generated stresses have the relationship of σ1b<σ1a. When the generated stresses σ1a and σ1b are substituted into (Formula 2) as the generated stress σ1, the following (Formula 3) is obtained. Generated stress σ1a×Area S1a+Generated stress σ1b×Area S1b<Pressure P1×Orifice area D (Formula 3). In this case, the force exerted on the inclined portion (generated stress σ1a×area S1a) is affected by the generated stress σ1a or the elastic force owned by the power driver 2 per se.

In (Formula 3), the orifice area D to which the pressure P1 is applied becomes equal to the area S1b on which the generated stress σ1b is exerted. That is to say (Formula 3) can be expressed as Generated stress σ1a×Area S1a+Generated stress σ1b×Area S1b<Pressure P1×Area S1b (Formula 4).

In the case of the area S1b in (Formula 4) being small and approximating zero, (Formula 4) approaches the relationship of Generated stress σ1a×Area S1a<0 (Formula 5). It is clear from (Formula 5) that the magnitude relation of the force exerted on the polymer actuator at the time of voltage application depends largely on the product of the generated stress σ1a and the area S1a. In addition, in (Formula 4), when the pilot valve is not in an open state, with each of the generated stress σ1a and the pressure P1 maintained constant, by reducing the orifice area D (area S1b), the value of Generated stress σ1b×Area S1b in (Formula 3) (or (Formula 4)) becomes relatively large and, therefore, the relationships of (Formula 3) and (Formula 4) are not satisfied. Thus, when (Formula 3) and (Formula 4) that are the conditions for the orifices 141 being not operated in an open state are not satisfied, the pilot valve is operated in an open state.

In the case of the diameter of the orifices being less than 0.25 mm, for example, since the orifice area D becomes smaller when the diameter is 0.25 mm, the pilot valve is likely to be in an open state from FIG. 37 even under pressure of 0.4 MPa. Even when the generated stress is lower than that at the time of voltage application in FIG. 37, the valve can be opened and closed under the pressure of 0.4 MPa. In short, since the generated stress and the applied voltage have close relationship, the voltage can be lowered.

In view of the above, when the case where the orifices 141 of the pilot valve 130 cannot be in an open state has been expressed in (Formula 3) and (Formula 4), the pilot valve is likely to be in an open state when reducing the orifice area D (area S1b). That is to say, when the orifices 141 have a small diameter, the function of the pilot valve can be enhanced.

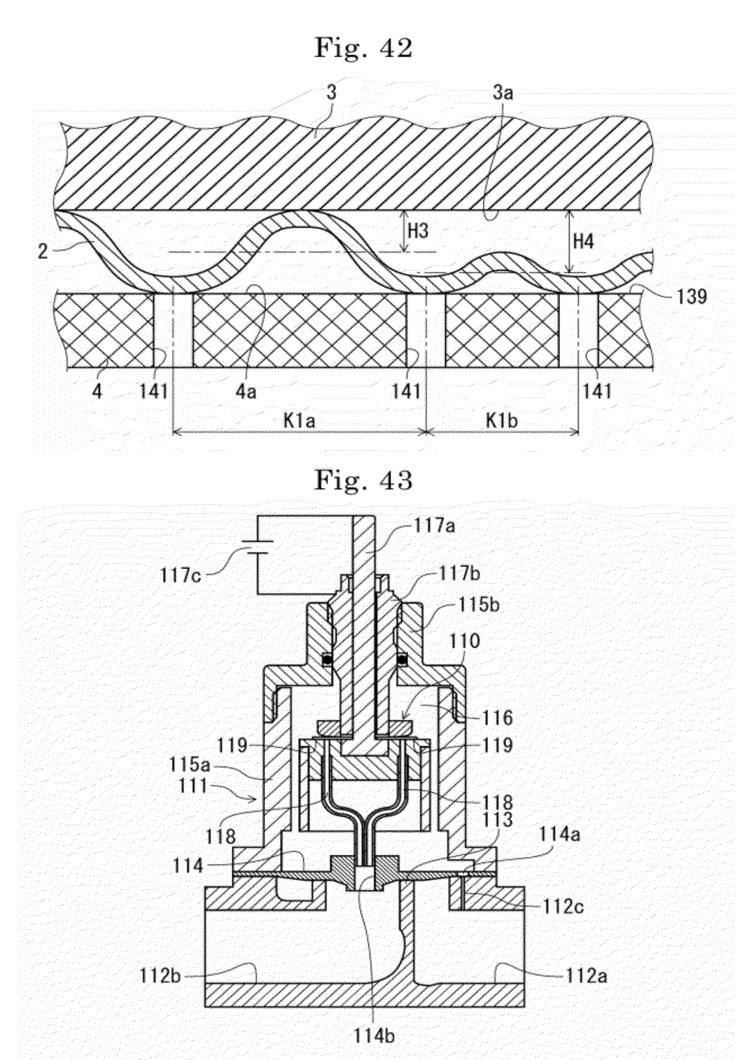

How the orifice interval affects the operation of the polymer actuator will be studied subsequently. FIG. 42 shows the state of the power driver 2 being operated relative to the orifices 141 disposed at different intervals. In the drawing, the orifices 141 and 141 are disposed at an interval K1a, and the orifices 141 and 141 are disposed at an interval K1b shorter than the interval K1a.

In the case where the power driver 2 is deformed at the time of voltage application, when the power driver 2 has been brought into contact with the fixed electrode 3 on the side of the valve seat portion 139 at the interval K1a, the power driver 2 assumes a shape in contact with the fixed electrode 3 at a center position of the interval K1a. Thus, the interval K1a between the adjacent orifices 141 and 141 has a bare distance necessary for part of the power driver 2 abutting on the abutment surface 3a of the fixed electrode 3. The interval K1a becomes the bare interval between the adjacent orifices 141 and 141. On the other hand, in the case of the orifices 141 and 141 disposed at the interval K1b, the fixed electrode cannot come into contact with the abutment surface 3a.

Assuming that an average distance from the power driver 2 to the abutment surface 3a at the interval K1a is set as H3 and that an average distance from the power driver 2 to the abutment surface 3a at the interval K1b is set as H4, the relationship of the average distance H3<H4 comes into existence and it is found from the Coulomb's law that the generated stress in the interval K1a is larger than the generated stress in the interval K1b. For this reason, supposing that the pilot valve is not operated in an open state when the orifices 141 have been disposed on the power driver 2 at the interval K1a, the pilot valve is not operated when the orifices 141 have been disposed on the same power driver 2 at the interval K1b. In addition, when the orifices 141 have been disposed at an interval larger than the interval K1a, since the generated stress exerted on the inclined portion of the power driver 2 does not vary, the plural orifices 141 are disposed preferably at a pitch of the interval K1a.

Where the orifices have a diameter of 0.25 mm, for example, by disposing the orifices at the interval K1a of 2.7 mm from FIG. 37, the pilot valve can be operated under pressure of 0.4 MPa. In the case of disposing the orifices on a circumference having a large diameter at the interval K1a of 2.7 mm, since the number of orifices is increased to enlarge the total flow passage area, a large flow rate can be secured.

As described above, in the valve 131 of the present embodiment, the total flow passage area of the plural orifices 141 is larger than the flow passage area of the through-bore 134a formed in the main body 134, and plural orifices 141 having a small diameter are disposed. As a result, the generated stress in the polymer actuator acts on the load of fluid pressure to drive the pilot valve 130.

With this configuration, the valve 131 can be driven, with the function of the pilot valve 130 fulfilled with exactitude and, since the generated stress in the polymer actuator is enhanced, it is possible to control the pressure and flow rate at the same level as or high level than in an ordinary pilot valve utilizing a solenoid. Furthermore, it is possible to provide a pilot valve at higher performance, such as durability and response speed, than the ordinary pilot valve.

Since the amount of stroke or lift of the polymer actuator forming a gap capable of attaining maximum flow rate relative to the orifices 141 through further reduction of the diameter of the orifices can be further reduced, the response speed is further enhanced. As regards the gap capable of making the flow rate relative to the orifices 141 maximum, where the orifices have a diameter of 0.5 mm, it is necessary that the gap on the upper side of the orifices has a width of 0.125 and that the gap on the upper side of the orifices has a width of 0.0625 in the case of the orifices having a diameter of 0.25 mm. Therefore, when the deformation speed of the polymer actuator is constant, it is possible that the time until the orifice flow rate becomes the maximum can be suppressed to one half.

Since the spaced-apart distance between the power driver 2 and the abutment surface 3a of the fixed electrode 3 can be shortened, it is possible to increase the generated stress in accordance with the Coulomb's law and control a high-pressure fluid. Since the amount of stroke of the polymer actuator becomes small to reduce a load at the time of operation of the power driver 2 or an electrode generally having flexibility becomes small, the operation durability is enhanced.

It is preferable from the aforementioned results of measurement of the flow rate and pressure when varying the diameter of the orifices that plural orifices 141 having a diameter of 0.25 to 0.5 mm be disposed on the valve seat portion 139. It is further desirable that plural orifices 141 having a diameter of 0.25 mm or less be disposed on the valve seat portion 139.

In this case, by disposing the orifices 141 on the same circumference of the valve seat portion 139 at a prescribed pitch, the entire polymer actuator is uniformly deformed relative to the orifices 141, thereby enabling the pilot valve to be operated with effective stress generated. At this moment, preferably the prescribed pitch is 1.8 to 5.5 mm and it may be adopted that the orifices of the prescribed pitch are disposed on a portion of the valve seat portion other than the same circumference thereof, that the orifices are disposed on plural circumferences having different diameters to set the pitch between the adjacent orifices smaller or that the orifices are disposed at positions other than on the circumference.

The polymer actuator shown in FIG. 33 to FIG. 42 is an example of the pilot valve and is not limitative. It goes without saying that the polymer actuator shown in FIG. 33 to FIG. 42 is applicable a valve using a polymer actuator disposed as a valving element in a body having plural flow passages to control opening and closing of the flow passages and adjustment of the flow rate with the valving element.

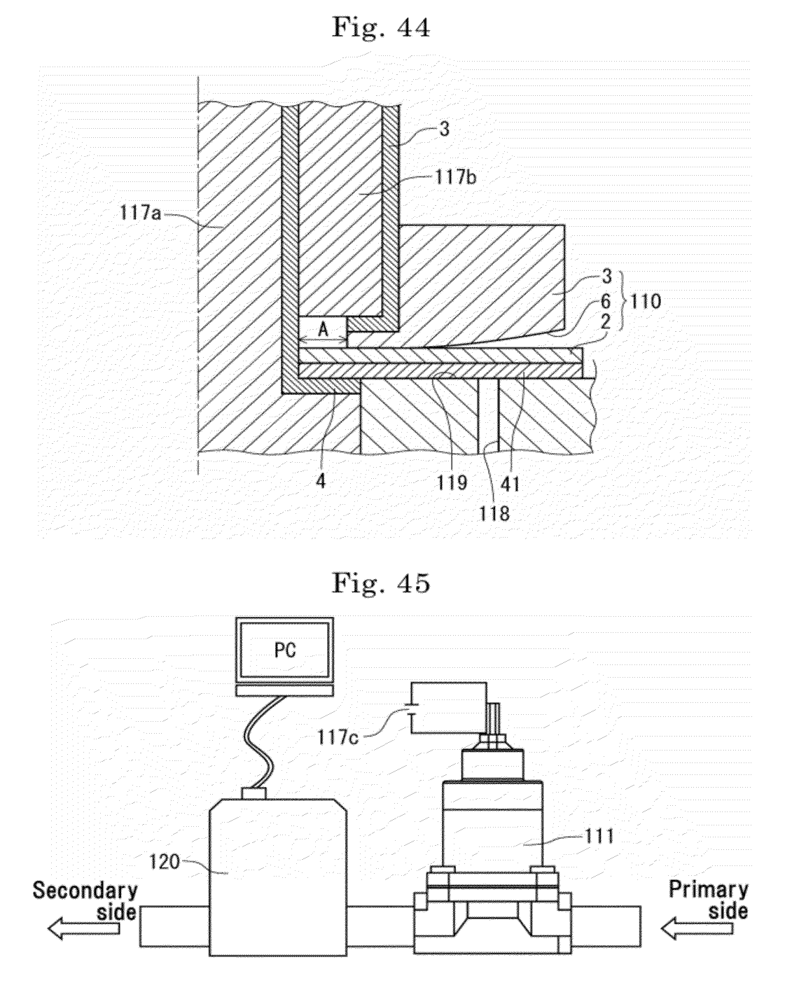

FIG. 43 shows another example of the valve provided therein with the pilot valve. The valve 111 has a primary-side flow passage 112a, a secondary-side flow passage 112b and an annular valve seat 113, is provided with a diaphragm 114 which has a through-bore 114a and which is capable of being seated on the annular valve seat 113, and has a structure in which, when a pilot valve 110 has been operated, the diaphragm 114 is operated as a valving element for opening and closing the flow passages to push up and close the valve. FIG. 44 is a partially enlarged view of FIG. 43, and FIG. 45 is a schematic view showing a flow measuring device using the pilot valve described above.

While the valve in FIG. 13 shown earlier shows the case capable of opening and closing control of air having pressure of 2.8 kPa, the valve of this embodiment enables opening and closing control of air having pressure of 20 kPa with the same voltage (0.75 kV) as in the embodiment of FIG. 13.

The pilot valve 110 is stored in a storage chamber 116 comprising a cover 115a and a cap 115b. The storage chamber 116 communicates with the primary-side flow passage 112a via a communication-hole 112c and a through-bore 114a. Similarly to the valve 131 described earlier, the valve 111 is suitable for an application requiring large flow rate. The pilot valve 110 may have a structure in which it is disposed outside the valve 111.

The pilot valve 110 is configured by the polymer actuator body comprising the power driver 2 having the flexible electrode 41, the fixed electrode 3 having the inclined surface 6 and the corresponding fixed electrode 4. In the figure, the power driver 2 is attached between a first power driver holder 117a and a second power driver holder 117b, and voltage is applied to the power driver 2 via the fixed electrodes 3 and 4. Reference numeral 117c denotes a power source for applying voltage to the fixed electrodes 3 and 4. Denoted by 118 is a communication passage communicating with the secondary-side flow passage 112b via a vent hole 141b of the diaphragm 114.

In the valve 111, application or application stoppage of voltage from the fixed electrodes 3 and 4 operates opening and closing the power driver 2 relative to a valve seat portion 119 provided at one end of the communication passage 118 to fulfill the function of the pilot valve. In this case, the pilot valve 110 is of a normally closed type in which the power driver 2 is operated in an open state at the time of voltage application.

In FIG. 44, a distance A is required for preventing discharge between the fixed electrodes 3 and 4 having different polarities. The distance A has to be made longer in accordance with the height of the applied voltage.

In FIG. 43 and FIG. 44, when the pilot valve 110 in a closed state, the valve seat 113 is closed by pressure of the storage chamber 116, and a state has been established in which the primary-side flow passage 112a communicates with the communication hole 112c, through-hole 114a and storage chamber 116 and the secondary-side flowing passage 112b communicates with the vent hole 114b and communication passage 118. At this time, since the areas receiving the pressure of the diaphragm 114 is larger on the secondary side than on the primary side, the diaphragm 114 is pushed against the valve seat 113. As a result, the primary-side flow passage 112a and secondary-side flow passage 112b are both closed.

Next, when the power driver 2 has been deformed through the application of voltage to the fixed electrodes 3 and 4, there by bringing the pilot valve 110 to an open state, since the pressure in the storage chamber 116 is released to the secondary-side flow passage 112b via the communication passage 118 and vent hole 114b, the diaphragm 114 receives the pressure only from the lower side and the diaphragm 114 is pushed upward by the pressure on the secondary side. As a result, the diaphragm 114 is separated from the valve seat 113 to supply the fluid from the primary-side flow passage 112a to the secondary-side flow passage 112b.

In this case, the results of measurement of flow rates at the time of voltage application with the measuring device shown in FIG. 45 are shown. FIG. 45 is a schematic view of the measuring device showing the state of measurement of flow rates at the time of applying voltage to the pilot valve 110 in the valve 111 of FIG. 43 provided on the secondary side thereof with a flow meter 120. At this time, where the pressure of 20 kPa was applied to the valve 111, when the pilot valve 110 was in an open state through the application of the voltage of 0.75 kV to the pilot valve 110, the flow rate of about 25 l/min could be secured. Thus, it is possible to flow the fluid at high flow rate through the operation of the polymer actuator as the pilot valve.

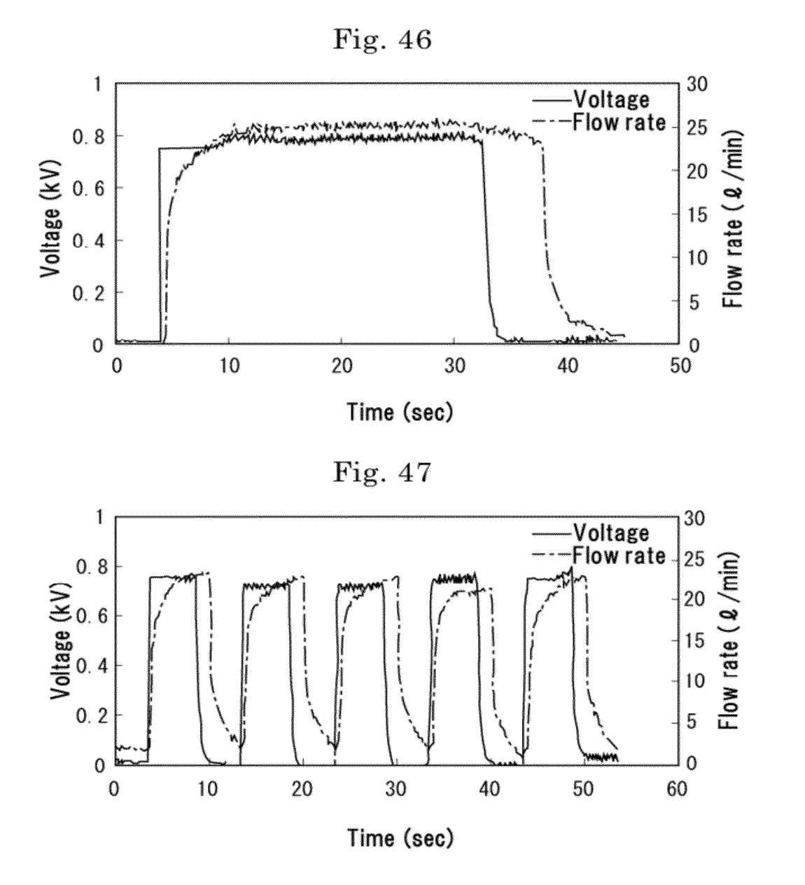

The relationship between the voltage and the flow rate of the valve 111 at that time is shown in a graph of FIG. 46. It can be confirmed from the graph that the response speed at the time of closing the flow rate when the application of voltage has been stopped is slow.

The relationship between voltage and flow rate obtained when the valve has repeatedly been opened and closed is shown in FIG. 47. At this time, the response speed from application of voltage to an open state allowing a fluid to flow is about 0.5 S and the response speed from stopping the application of voltage to an closed state in which no fluid flows is about 2.0 S. It is thought that this difference in response speed results greatly from the fact that the power driver 2 of the pilot valve 110 is bent due to the orientation of molecules, Coulomb's force, and injection and eccentric location of charges at the time of voltage application and the opposite fact that the power driver 2 returns to its original position owing to its elasticity when the application of voltage has been stopped. It is also thought that the response speed is delayed because the power driver 2 adheres to the electrodes due to remnant of the stress generated at the time of voltage application and adhesiveness of the power driver 2. Incidentally, the response speed here refers to the time from the on-off operation of voltage to the attainment of a value of 63.2% (time constant) of the final value (25 l/min).

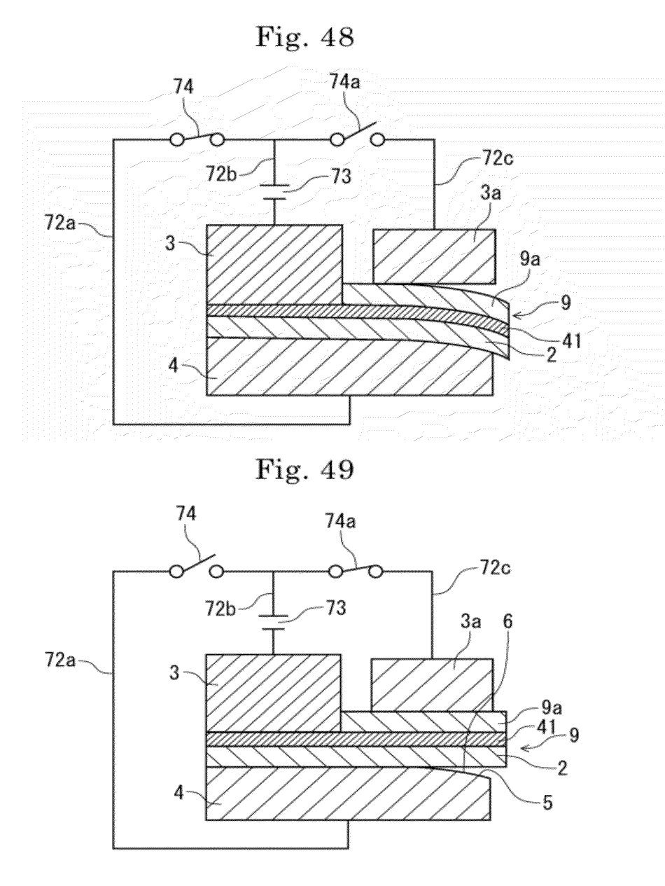

FIG. 48 and FIG. 49 show another embodiment of the polymer actuator, according to which the state in which the response speed is delayed at the time of closing the flow rate shown in FIG. 46 and FIG. 47 can be resolved. The resolving means will be described hereinafter.

In the same figures, a stacked power driver 9a is stacked on the power driver 2 via the flexible electrode 41 to form a driving member 9, and a fixed electrode 3a is further disposed on the stacked power driver 9a to enhance the response performance of the driving member 9 at the time closing.

In this case, the fixed electrodes 4, 3 and 3a are connected to the power source 73 respectively via power circuits 72a, 72b and 72c, and switches 74 and 74a are disposed midway the power circuits.

FIG. 48 shows the state in which the power driver has been bent downward, and FIG. 49 shows the state of the power driver having been bent upward. In the case of bending the power driver downward, as shown in FIG. 48, the switch 74 is turned on, the switch 74a is turned off, positive voltage is applied to the fixed electrode 4, and negative electrode is applied to the flexible electrode 41 via the fixed electrode 3. On the other hand, in the case of bending the power driver upward, as shown in FIG. 49, by turning the switch 74a on and the switch 74 off and applying positive voltage to the fixed electrode 3a and negative voltage to the flexible electrode via the fixed electrode 3, the response speed in each of valve-opening and valve-closing states becomes about 0.5 S and, therefore, it is possible to resolve the state in which the response speed is delayed at the time of valve-closing.

As shown in the same figures, by stacking the stacked power driver 9a to constitute the driving member 9, since the function of the stacked power driver 9a can be fulfilled as the polymer actuator even when returning the power driver to its original position, the power driver is forcibly deformed to its original position due to the orientation of molecules, Coulomb's force, and injection and eccentric location of charges and, therefore, the driving member 9 can obtain high response performance in both the upward and the downward directions. Incidentally, it goes without saying that the polymer actuator shown in FIG. 48 and FIG. 49 is applicable to the valves shown in FIG. 11, FIG. 12 and FIG. 13.

### Example 1

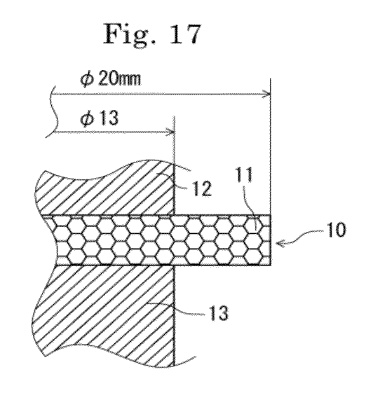

The actuator body 1 equipped with the fixed electrode 4, possessed of the inclined surface 6 shown in FIG. 1 and used as a sample A was formed to have dimensions shown in FIG. 16, and the amount of displacement of the power driver 2 was measured with the displacement measurement device 100. On the other hand, the actuator member 10 shown in FIG. 3 was formed to have dimensions shown in FIG. 17 as a comparative sample a, and the amount of displacement of the power driver portion 11 was similarly measured. The power driver 2 in the sample A in FIG. 16 was formed of ester polyurethane having 0.5 wt % of tetrabutylammonium chloride added thereto and formed to have a diameter of 20 mm and a thickness of 0.1 mm. On the other hand, the negative fixed electrode 4 is formed with the inclined surface 6 and the positive fixed electrode 3 is fixed wholly to the power driver 2.

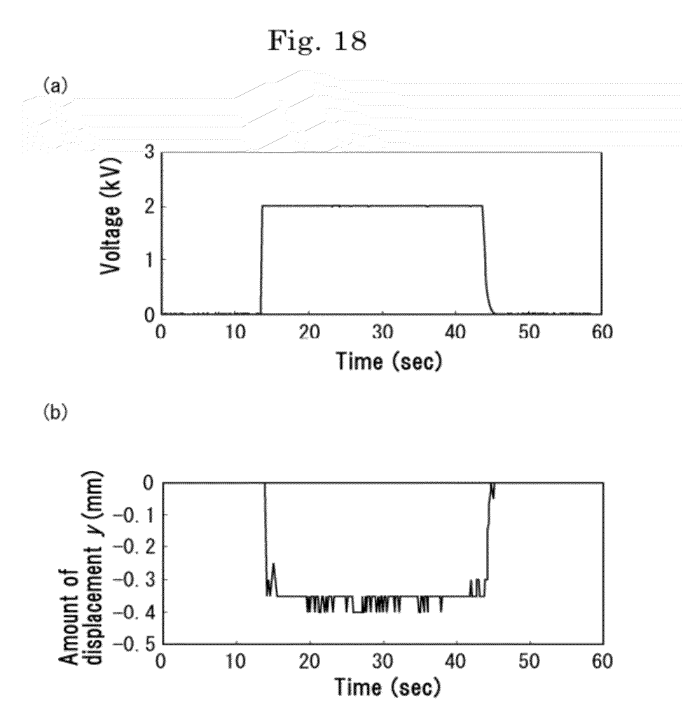

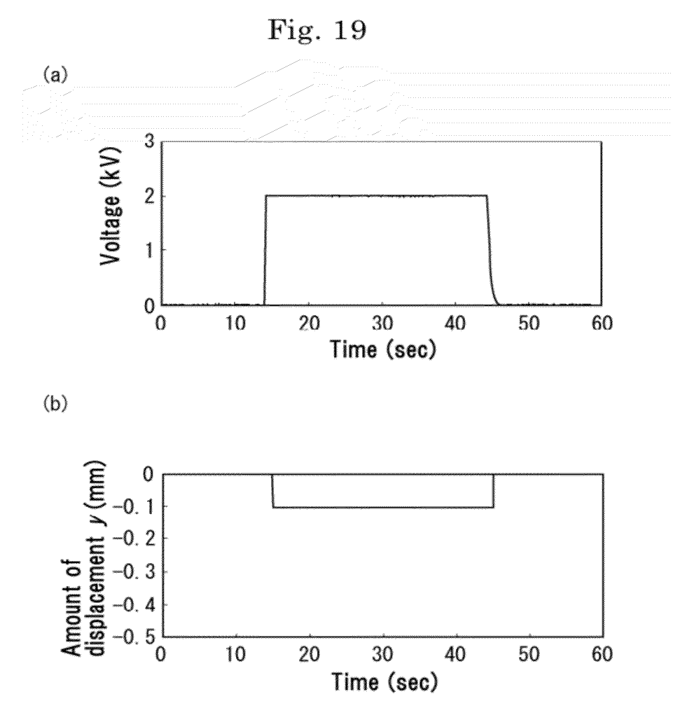

The voltage application state when voltage of 2 kV has been applied to the sample A for a prescribed time is shown in FIG. 18(a), the results of measurement of the amount of displacement in the power driver 2 at the time of voltage application are shown in FIG. 18(b), the voltage application state when voltage of 2 kV has been applied to the comparative sample a for a prescribed time in FIG. 19(a), and the results of measurement of the amount of displacement in the power driver portion 11 at the time of voltage application in FIG. 19(b).

It was found from the results of measurement that the amount of displacement in the sample A shown in FIG. 18(b) was about 0.35 mm ant that the amount of displacement in the comparative sample a shown in FIG. 19(b) was about 0.1 mm. Therefore, it was confirmed from the experiments that the specimen A became larger in amount of displacement than the comparative sample a.

### Example 2

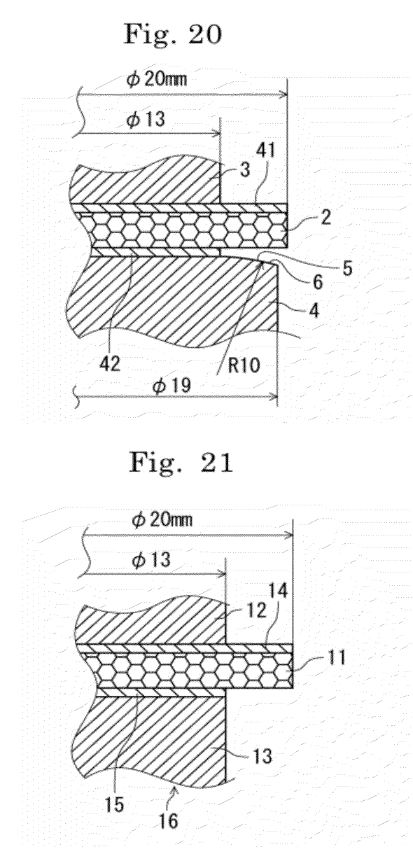

The actuator body 40 possessed of the circular-arc surface inclined surface 6 and shown in FIG. 7 had the power driver 2 provided with the flexible electrodes 41 and 42 and was used as a sample B formed to have dimensions of FIG. 20. The power driver 2 in the sample B was formed of ester polyurethane having 0.5 wt % of tetrabutylammonium chloride added thereto and formed to have a diameter of 20 mm and a thickness of 0.1 mm. The power driver 2 was provided with a thin gold film formed by sputtering on the minus side to have a diameter of 16 mm or less and with a gold film formed by sputtering on the plus side over the entire surface thereof. On the other hand, the fixed electrode 4 on the minus side is formed with the inclined surface 6 in the shape of a circular arc, and the fixed electrode 3 on the plus side is entirely fixed to the power driver 2.

FIG. 21 shows a comparative sample b that is an actuator member 16 having the actuator member of FIG. 3 provided with flexible electrode portions 14 and 15. The power driver portion 11 in the comparative sample b has a conventional structure in which the fixed electrode portion 13 has no abutting surface. The power driver portion 11 is provided on the minus side thereof with a thin gold film 16 mm or less in diameter formed by sputtering to constitute the flexible electrode portion 15 and on the plus side thereof with a thin gold film entirely formed by sputtering to constitute the flexible electrode portion 14.

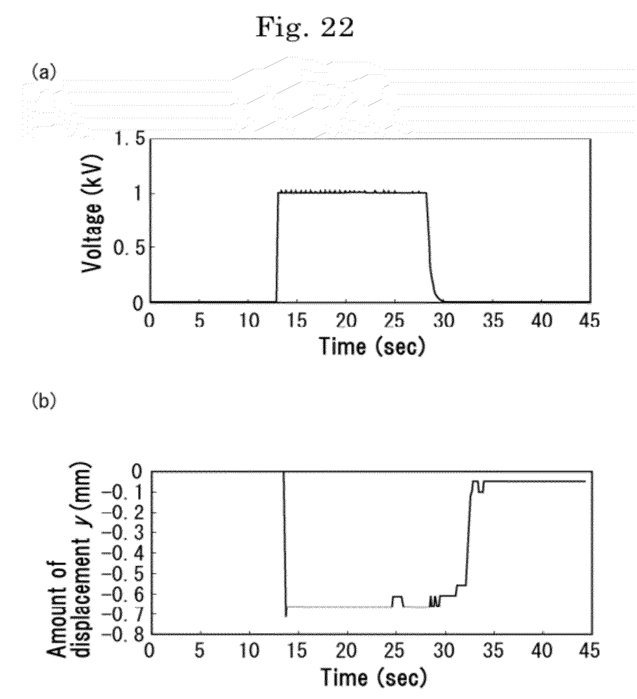

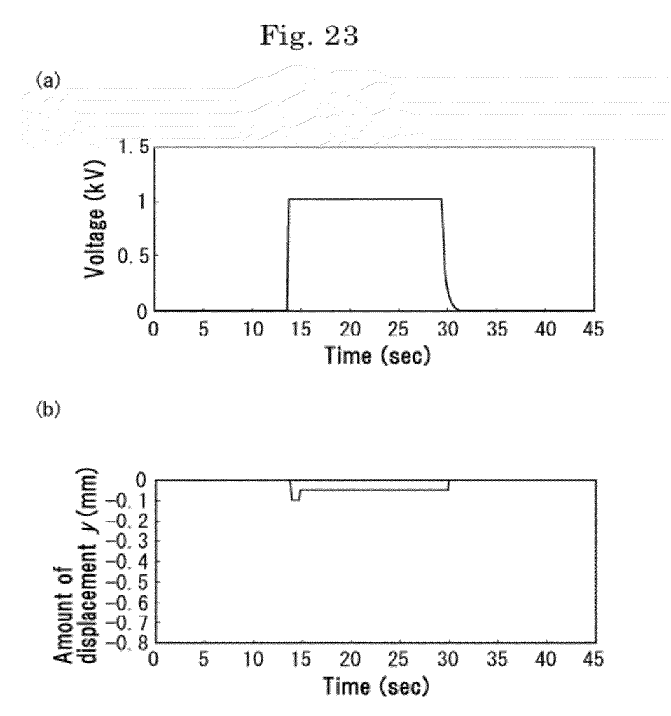

The voltage application state when voltage of 1 kV has been applied to the sample B for a prescribed time is shown in FIG. 22(a), the results of measurement of the amount of displacement of the power driver 2 at the time of pressure application are shown in FIG. 22(b), the voltage application state when voltage of 1 kV has been applied to the comparative sample b for a prescribed time in FIG. 23(a), and the results of measurement of the amount of displacement of the power driver portion 11 at the time of pressure application in FIG. 23(b).

It was confirmed from the results of measurement that when the voltage of 1 kV was applied, the amount of displacement of the sample B in FIG. 20 was about 0.65 mm as shown in FIG. 22(b) and that the amount of displacement of the comparative sample b in FIG. 21 was about 0.05 mm as shown in FIG. 23(b). It was therefore confirmed that the amount of displacement in the sample B becomes larger than in the comparative sample b and further that the ratio between the amounts of displacement in the sample and comparative sample became large as compared with that in the experiments of Example 1. It was therefore confirmed that the sample B having the fixed electrode provided with the abutting surface and having the power driver provided with the flexible electrode obtained a larger amount of displacement.

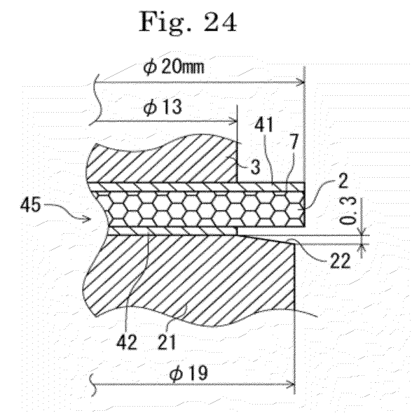

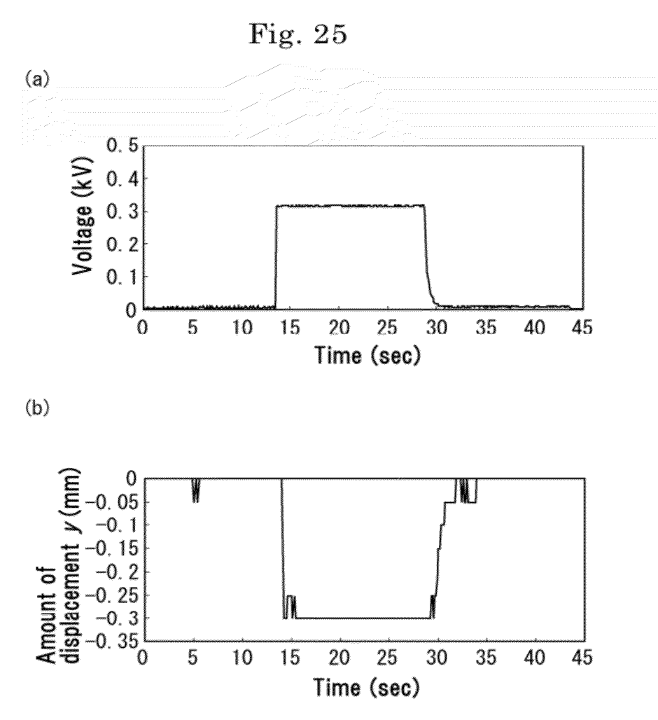

In addition, the actuator body 45 in FIG. 8 was formed to have dimensions in FIG. 24 and used as a sample C. The voltage application state when voltage of 0.3 kV has been applied to the sample C for a prescribe time is shown in FIG. 25(a), and the results of measurement of the amount of displacement in the power driver 2 at the time of voltage application are shown in FIG. 25(b). It was confirmed from the results of measurement and those in FIG. 23 that the sample C obtained a larger amount of displacement at a smaller amount of applied voltage as compared with the comparative sample b in FIG. 21. Incidentally, the distance between the outer end portion of the abutment surface and the power driver can be set from the amount of displacement necessary for an actuator. The circular-arc shape shown in FIG. 16 desirably has an R of 5 or less and, in the case of the tapered shape shown in FIG. 24, the inclined surface of the abutment surface desirably has an inclination of 45 degrees or less. In addition, since the distance between the outer end portion of the abutment surface and the power driver is determined from the amount of displacement necessary for the actuator, the tapered shape is better than the circular-arc shape from the standpoints of design and workability.

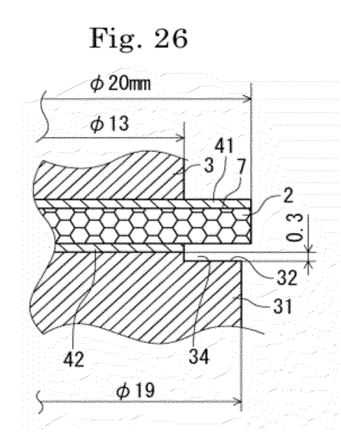

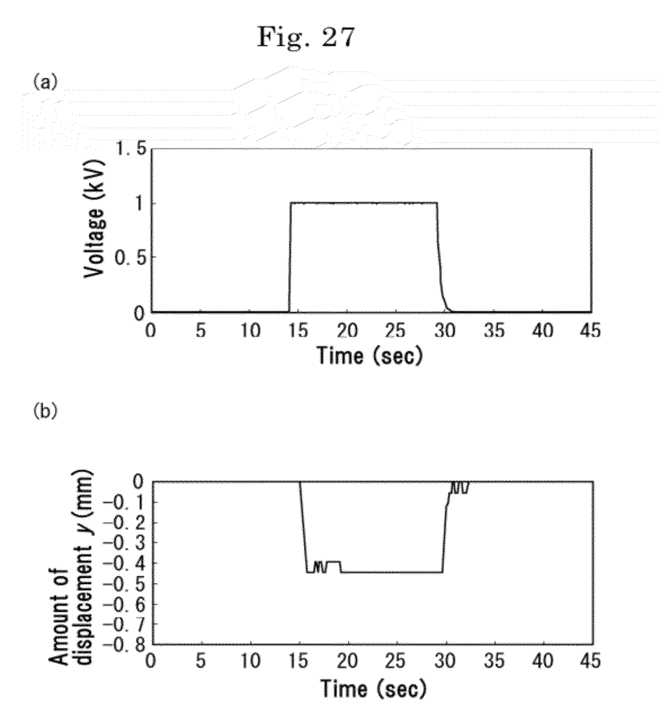

The actuator body 55 shown in FIG. 10 was formed to have dimensions shown in FIG. 26 and used as a sample D. The voltage application state when voltage of 1 kV has been applied to the sample D for a prescribed time is shown in FIG. 27(a), and the results of measurement of the amount of displacement in the power driver at the time of voltage application are shown in FIG. 27(b). It was confirmed from the results of measurement and those in FIG. 23 that the sample D obtained a larger amount of displacement at the same applied voltage as compared with the comparative sample b of FIG. 21.

### Example 3

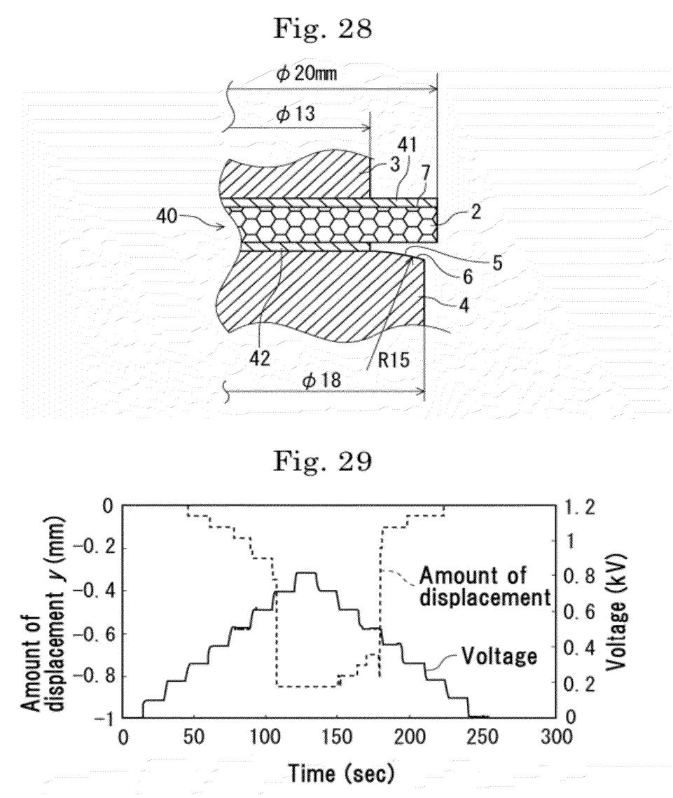

Subsequently, the actuator body 40 shown in FIG. 7 was formed to have dimensions shown in FIG. 28 and used as a sample E. The voltage applied to the sample E was stepwise increased by 0.1 kV to bend and deform a deformed portion of the power driver 2 and displace the power driver until the power driver came into contact with the inclined surface 6 of the fixed electrode 4 and, thereafter, the applied voltage was stepwise decreased by 0.1 kV. The changes in voltage and changes in amount of displacement of the power driver at that time are shown in FIG. 29.

It is found from the results of measurement in FIG. 29 that there is a case where the amounts of displacement differ when the applied voltage is raised and lowered even at the same applied voltage and that the traces of changes in amount of displacement differ in the cases of voltage ascent and descent. To be specific, when the applied voltage has been raised to 0.7 kV, the amount of displacement is increased and, when the applied voltage has be lowered to 0.7 kV, the shape is not returned to the original position. However, when the applied voltage has been lowered to 0.4 kV, the shape is greatly deformed to the original shape. It is said that, in the actuator body 40 unlike the conventional actuator having substantially the proportional relationship between the applied voltage and the amount of displacement, the flow rate changed largely in consequence of the applied voltage ascent can be maintained at the applied voltage lower than that at the time of the voltage ascent.

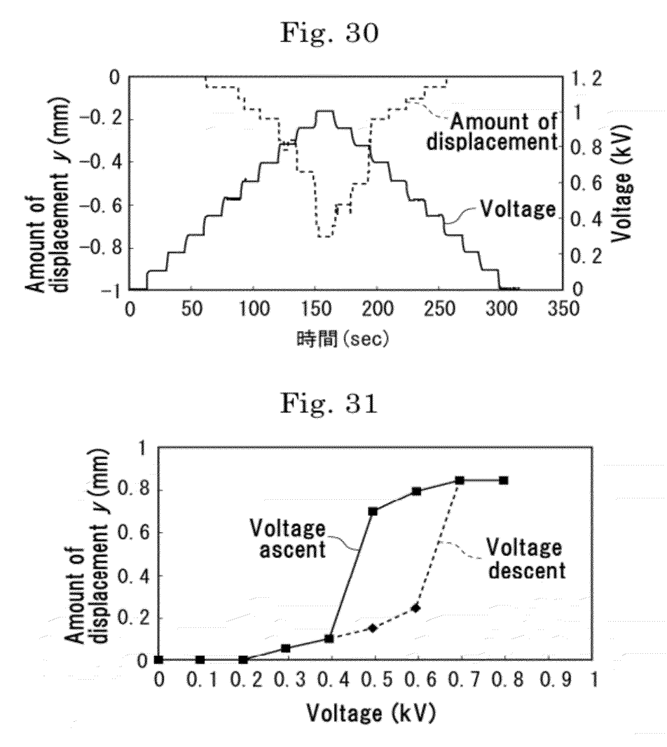

Subsequently, the actuator body 40 of FIG. 28, in which the abutment surface 5 of the power driver 2 had surface roughness of 25, was used as a sample F. Similarly to the case of the sample E, the voltage applied to the sample F was stepwise raised and lowered by 0.1 kV. The change in voltage and the amount of displacement of the power driver 2 at that time are shown in FIG. 30. In addition, when the applied voltage and the amount of displacement at that time taken on the horizontal and vertical axes in a graph, respectively, are shown in FIG. 32 and, similarly to the graph, the changes in amount displacement relative to the voltage applied to the sample E are shown in a graph of FIG. 31. Incidentally, in the sample E, the surface roughness is 1.6. The surface roughness referred to herein indicates center line average roughness.

It is said from the comparison between FIG. 30 and FIG. 29 that the sample F of FIG. 30 varies so that the amount of displacement may be more proportionate to the applied voltage. That is to say, the graph of FIG. 32 is straighter than the graph of FIG. 31. It was confirmed that the surface roughness set to be 25 enabled the relationship between the applied voltage and the amount of displacement to approach the proportionate relationship. Thus, the sample F is suitable particularly for linear control and also for minute flow rate control because the amount of displacement varies in proportion to the variation in applied voltage. The sample F or sample E is suitable for on-off control utilizing the response that obtains a specific amount of displacement relative to specific applied voltage and is applicable to various kinds of control instruments utilizing the fact that different amounts of displacement can be obtained relative to the prescribed applied voltage in FIG. 29 or FIG. 30.

### EXPLANATION OF REFERENCE NUMERALS

1: actuator body
2: power driver
3, 4: fixed electrodes
3a, 4a: abutment portions
5: abutment surface
6: inclined surface
9: driving member
9a: stacked power driver
41, 42: flexible electrodes
60, 80: valve bodies
61: body
62, 63: flow passages
130: pilot valve
132a: primary-side flow passage
132b: secondary-side flow passage
134: piston (valving element for opening and closing the passages)
134a: through-bore
139: valve seat portion
141: orifice
G: stepped region
T: spaced-apart region

1. A polymer actuator comprising:
a power driver deformed upon receiving external electro stimuli; and
fixed electrodes disposed on upper and lower surface sides of the power driver in an opposite manner for applying positive and negative external electro stimuli to the power driver in a planar fashion;
wherein at least one of the fixed electrodes extends to a side, on which the power driver is deformed, and has an abutment surface displaced by means of the Coulomb force when the power driver has been deformed, thereby enabling the abutment surface to come into contact with the power driver and, at a time of application of no external electro stimuli, the abutment surface of one of the fixed electrodes forms a spaced-apart region between itself and the power driver.

2. A polymer actuator according to claim 1, wherein the spaced-apart region is provided with an inclined surface, including a circular-arc surface, a radiation surface and a tapered surface, with which the abutment surface and the power driver are gradually spaced apart from each other in an outer end direction.

3. A polymer actuator according to claim 1, wherein the spaced-apart region is provided with a stepped region.

4. A polymer actuator according to claim 2, wherein the power driver has a flexible electrode disposed on a surface opposite to at least the abutment surface and deformed together with the power driver to apply external electro stimuli to the power driver.

5. A polymer actuator, comprising a driving member that comprises power drivers stacked via the flexible electrode in claim 4 to form a stacked power driver, wherein the stacked power driver has a fixed electrode disposed thereon to enhance response performance of the driving member.

6. A polymer actuator according to claim 1, wherein the abutment surface has surface roughness of 25 to 500.

7. A valve using the polymer actuator according to claim 1, comprising a body provided therein with plural flow passages and having the polymer actuator disposed therein as a valving element for controlling opening and closing the flow passages or controlling flow rate.

8. A polymer actuator according to claim 1, wherein the power driver is used as a pilot valve for opening and closing a diaphragm- or piston-type main valve.

9. A polymer actuator according to claim 8, wherein the pilot valve has a valve seat portion that is provided on a circumference thereof with plural bored orifices allowed to communicate with a communication passage on a secondary side.

10. A polymer actuator according to claim 8, wherein the plural orifices have a total flow passage area larger than a flow passage area of through-bores formed in the main valve, and plural orifices having small diameters are disposed to cause generated stress in the polymer actuator to act on fluid pressure load, thereby driving the pilot valve.

11. A valve using the polymer actuator according to claim 8 having the valve seat portion that is provided with the plural orifices, wherein the orifices respectively have a diameter in a range of 0.25 to 0.5 mm.

12. A valve using the polymer actuator according to claim 8 having the valve seat portion that is provided with the plural orifices, wherein the orifices respectively have a diameter of 0.25 mm or less.

13. A valve using the polymer actuator, according to claim 9, which has the valve seat portion provided on the circumference thereof with the plural orifices, wherein the orifices are disposed at a prescribed pitch.

14. A valve using the polymer actuator according claim 13, wherein the prescribed pitch is in a range of 1.8 to 5.5 mm.
